(19) United States
(12) Patent Application Publication
(10) Pub. No.: US 2011/0204407 A1
(43) Pub. Date: Aug. 25, 2011

(54) Power LED device with a reflector made of aromatic polyester and/or wholly aromatic polyester

(75) Inventors: Glenn W. Cupta, Roswell, GA (US); Christie W. Crowe, Alpharetta, GA (US); Nancy J. Singletary, Alpharetta, GA (US); Maria G. Bertucci, Cumming, GA (US); Jan G. Nel, Appling, GA (US); Geert J. Verfaillie, Parike (BE)

(73) Assignee: SOLVAY ADVANCED POLYMERS, L.L.C., Alpharetta, GA (US)

(21) Appl. No.: 13/126,491

(22) PCT Filed: Oct. 30, 2009
(86) PCT No.: PCT/EP09/64400

§ 371 Date: Apr. 28, 2011

Related U.S. Application Data
(60) Provisional application No. 61/140,647, filed on Dec. 24, 2008.
(60) Provisional application No. 61/109,537, filed on Oct. 30, 2008.

(51) Int. Cl. H01L 33/60

(52) U.S. Cl. 257/98; 257/E33.072

(57) ABSTRACT

A Power LED device including a reflector and a light emitting diode (LED). The reflector is made of aromatic polyester and/or wholly aromatic polyester.

### CROSS REFERENCE TO RELATED APPLICATIONS

The present application claims the priority benefit to U.S. provisional application No. 61/106,177 filed on Oct. 30, 2008, and to U.S. provisional application No. 61/140,647 filed on Dec. 24, 2008, the whole content of these applications being herein incorporated by reference for all purposes.

### BACKGROUND OF THE INVENTION

1. Field of the Invention

A reflector for a Power LED (PLED) device made from a composition comprising an aromatic polyester and/or a wholly aromatic polyester. A Power LED device including a Power LED for emitting light and/or radiation and a reflector made from a composition comprising an aromatic polyester and/or a wholly aromatic polyester. Articles containing the Power LED device including lighting devices and optoelectronic devices are also included in the invention. A Power LED device for operating at high junction temperatures or made using high reflow temperatures.

2. Description of the Related Art

A Light Emitting Diode (i.e., an LED) is a microelectronic structure that contains a material which emits light when driven with electrical energy, e.g., a p-n junction semiconductor that emits incoherent optical radiation when biased in the forward direction. LED devices are assemblies of components which form a device for emitting radiation such as light. LED devices contain one or more LEDs in addition to other components necessary for driving the LED, positioning the LED, and mounting the LED in an end-use device. Typically, LED devices include a frame, an LED, leads connected to the LED, and an assembly package.

The LED device conventionally includes a heat sink which is in thermal contact with the LED. The heat sink serves to absorb and dissipate heat generated during operation of the LED device. Heat sinks used in LED applications take a variety of forms and are typically made from materials having good thermal conduction and, optionally, poor electrical conduction. In some LED devices the heat sink functions as a cathode or anode lead connecting the LED to a source of electricity.

The LED is usually held in place on the top of the heat sink and/or the bottom of the reflector with an adhesive material. The LED may be potted and/or bonded to the heat sink or any other component of an LED device by one or more different adhesive or encapsulating materials.

Reflectors may be included in LED devices to focus, color and/or collimate light emitted by the LED. LED reflectors are typically molded onto a frame which is subsequently connected to an LED in the form of a chip. The reflector may be integral with the heat sink, for example the reflector and heat sink may form a single molded part.

Power LED (PLED) devices are devices that emit much greater amounts of light than conventional LED devices such as top view and side view LED devices. Power LED devices generate substantially greater amounts of heat and light than conventional LED devices and are thus exposed to much greater stress in comparison to conventional LED devices. Power LEDs are typically driven at from 150 mA to over 1,000 mA whereas conventional LEDs are driven at less than 150 mA, possibly down to 1 mA or less. The substantial increase in stress encountered during Power LED operation results in accelerated and more pronounced degradation effects such as discoloration and physical deterioration of reflectors and or assembly housings.

The materials used to make the components of conventional LED devices often include thermoplastic polymers. Thermoplastic materials are, in general, electrically insulating and may thus be used for making certain components of certain LED devices. Some thermoplastic materials may be imparted with electrical conduction properties by the inclusion of certain additives and/or, in the case of certain specialty thermoplastics, the underlying thermoplastic may itself have electrically conductive properties. The use of thermoplastic insulators is advantageous because they can be mass produced quickly and efficiently. Conventional thermoplastic materials, however, suffer from thermal and radiation sensitivity. Further still, many thermoplastic materials are inherently discolored (e.g., they exhibit yellow color characteristics) and may thus affect the color of reflected light.

Thermoplastic materials undergoing thermal stress and/or exposure to intense radiation suffer not only from discoloration but also from the loss of desirable physical properties such as elasticity and thus may become brittle. On exposure to high heat and/or on exposure to radiation such as intense light, the polymer backbone of thermoplastic materials may be degraded leading to a substantial reduction in the elastic properties of the original thermoplastic material. The resulting brittle materials may be susceptible to fracture and/or adhesion.

Besides, LED devices are subject to high heat and radiative stress during operation and during manufacture which involves several cycles of exposure to high heat. LED devices are typically manufactured in a process that includes first molding one of more of the features of the LED device onto a frame. The molding can be carried out by conventional molding techniques such as injection and/or compression molding and the like. During this molding the material from which the features (e.g., a reflector) are made are subjected to high temperature, i.e., a temperature greater than the glass transition or melting temperature of the material.

The resulting part that contains a feature molded onto a lead frame is then bonded to a chip that provides the LED function to the device. The chip is a semiconductor device that comprises a light emitting diode. Conventional LEDs are bonded to the lead frame with conductive epoxy or other adhesive materials. The conductive epoxy is typically cured by heating at a temperature of up to about 180° C. for a period of time that ranges from 0.5 to 6 hours. Power LEDs may be bonded to the lead frame by soldering. The soldering process can include subjecting a least a portion of the lead frame and chip to temperatures of over 300° C. as the lead frame is contacted with a molten solder composition. The chip is wirebonded to the lead frame after the chip has been connected to the lead frame. Wire bonding may include soldering which again subjects the LED device to temperatures that may be greater than 300° C.

The wire-bonded device is then encapsulated with a synthetic material such as a thermosetting or thermoplastic composition. Encapsulation typically involves curing the thermosetting or thermoplastic composition at an elevated temperature (e.g., 60-180° C.) for a period from 0.5 to 6 hours to form an LED package or device.

The LED package is subjected to another heat cycle as it is mounted onto a printed circuit board. The LED package may be affixed to the printed circuit board by techniques such as soldering during which portions of the LED package are contacted with a molten solder composition.

In addition to the above mentioned process steps a further drying step(s) may be carried out. The drying functions to remove water which may have been absorbed by any component of the LED device during its manufacture. Drying may be carried out, for example, under infra-red reflow conditions which include heating to temperatures as high as 260° C. for a period of minutes.

As a consequence of the production process any material from which the LED device is made may be subject to a temperature that is substantially higher than the operating temperature of the LED device. Thus even before being set into service a component from an LED device such as an LED reflector made from a thermoplastic material may have a significant heat history. Especially for thermoplastic materials this heat history may lead to degradation and coloring of, e.g., the reflector.

U.S. 2004/0165390, incorporated herein by reference in its entirety, discloses a liquid crystalline polyester for use as a reflector plate in liquid crystal display devices and electronic devices that include LED components. The polyester resin from which the reflector plate is made includes polymerized aromatic monomer units. The reflector plate has a yellowness index of 32 or less. The patent application does not disclose the use of a wholly aromatic LCP to make a component of a Power LED device.

JP 2004-277539, incorporated herein by reference in its entirety, discloses a liquid crystalline polyester resin for producing a reflector. The resin may be made from aromatic diol and aromatic dicarboxylic acid monomer units.

U.S. Pat. No. 7,138,667, incorporated herein by reference in its entirety, discloses a conventional LED device in which an LED is bonded to a heat sink which also serves as an electrical connection between the LED and an electrical source. The LED is also electrically connected to the electrical source by another means such as a wire which contacts a surface of the LED not in contact with the heat sink. A liquid crystalline polyester (LCP) is used as a material for making an assembly that functions to hold the heat sink and the LED and further for forming a lead frame component of the LED device. The patent does not disclose the use of a wholly aromatic LCP to make a component of a Power LED device.

WO 2006/064032, incorporated herein by reference in its entirety, discloses the use of certain polymers such as semi-crystalline polymers (SCP) in combination with metal oxides and/or nitrides to form portions of an emission apparatus. The semi-crystalline polymer/metal oxide composition may be used to form housing components of the emission apparatus and/or heat sinks used in the emission apparatus. The use of a wholly aromatic LCP to make a component of a Power LED device is not disclosed.

U.S. Pat. No. 7,273,987, incorporated herein by reference in its entirety, describes flexible interconnect structures with surface mounted LED devices. The LED devices may be mounted on a flexible polymer substrate which is formed from thermoplastic polymers including polyester materials. Power LEDs are not disclosed nor is the use of a wholly aromatic LCP to make any components of the LED device.

U.S. Pat. No. 6,541,800, incorporated herein by reference in its entirety, discloses an LED device that includes a heat sink directly bonded to an LED. Direct contact between the LED and the heat sink provides for good thermal conduction away from the LED. An LCP is used to separate the cathode and anode components of the LED package. Properties such as thermal conductivity and electrical insulativity permit the LCP to provide advantages in thermally connecting the anode and cathode components of the LED package. The patent does not disclose the use or inclusion of a wholly aromatic LCP or a composition comprising an LCP as a way to separate anode and cathode components or as a material useful for making components of a Power LED device such as a reflector.

U.S. 2006/0292747, incorporated herein by reference in its entirety, discloses a surface mount power light emitter having an integral heat sink. The light emitter may be a device such as an LED. The surface mount power light emitter includes a thermally conductive substrate. When the substrate is made out of a metallic, electrically conductive material such as aluminum or copper, a dielectric layer may be present between the substrate and the LED. The substrate alternately made from a high temperature plastic such as an LCP filled with a thermally efficient material. The inclusion of a wholly aromatic LCP as a component of the substrate and/or heat sink is not disclosed nor is the use of a wholly aromatic LCP to form a reflector component of the surface mount power light emitter described.

U.S. 2007/0291503, incorporated herein by reference in its entirety, discloses LEDs formed on flexible circuit boards. The circuit board may contain layers of a flexible thermoplastic material such as a polyester. Direct contact between the LED and the flexible circuit board allows thermal and/or electrical conduction to occur. In addition, thermoplastic materials such as polyester may be used in other layers of the flexible circuit board not in direct contact with the LED but still serving to dissipate heat. The use of a wholly aromatic LCP to form a reflector component is not disclosed.

U.S. Pat. No. 6,599,768, incorporated herein by reference in its entirety, also discloses a method for surface mounting high Power LEDs onto a substrate. The substrate serves as a thermal sink. Preferred substrate materials include metals which have substantially higher thermal conductivity than electrical insulators such as silicon. Transparent polymers such as thermosets may be used to form a clear protective layer over LED. The use of a wholly aromatic LCP to form a Power LED device is not disclosed.

U.S. Pat. No. 7,202,505, incorporated herein by reference in its entirety, discloses an LED assembly that includes Power LEDs. The use of a wholly or highly aromatic polyester to form a thermal sink or reflector of the LED device is not disclosed.

JP 2007-300018, incorporated herein by reference in its entirety, discloses a device for emitting light that includes an LED. The LED device includes a reflector component made from a metal material. Metal is used to avoid problems associated with the use of thermoplastic materials which are disclosed to suffer from yellowing under conditions of long use and heat. The publication discloses that the brightness of the LED device may fall about 50% if the LED device contains a reflector component made from a resin undergoing yellowing. The use of a wholly or highly aromatic polyester to make the reflector is not disclosed.

JP 2007-300018, incorporated herein by reference in its entirety, discloses a high Power LED package including a housing made from an insulating material such as an injection material. Insulative films such as polyimide films may be present in portions of the LED package.

As it will be understood, conventional LED devices such as those mentioned above may include reflector components made from conventional thermoplastic materials, in particular conventional polyesters such as aliphatic polyesters.

Reflectors for Power LEDs require an especially demanding combination of excellent color and improved physical properties such as high heat distortion temperature, high elongation, and/or high melt viscosity. Conventional polyesters are unable to provide each of these attributes in a single resin. More generally, the use of conventional thermoplastic materials in Power LED devices is disfavored due to thermal and radiative degradation of the thermoplastic material which causes changes in the color of light perceived to be emitted from the Power LED device.

Power LED devices can suffer from light distortion and/or poor emission efficiency after exposure to the high temperature and high intensity radiation. These problems are due at least in part to the degradation of materials used to make components of the PLED devices that reflect emitted light. This degradation may include discoloration and/or physical deterioration of components such as reflectors and thermal sinks.

### SUMMARY OF THE INVENTION

The inventors have discovered that the use of aromatic polyesters and/or wholly aromatic polyesters (PEs), usually liquid crystalline polyesters (LCPs), as matrix materials in Power LED devices provides Power LED devices having significantly superior emission stability, color consistency and longer useable lifetime.

The aromatic polyester of the invention (usually, an LCP) or the wholly aromatic polyester of the invention (also usually, an LCP), or compositions comprising the aromatic polyester and/or the wholly aromatic polyester of the invention, may be used to make components of Power LED devices such as heat sinks, connective material, and reflectors. The aromatic polyester and/or the wholly aromatic polyester of the invention, alone or in combination with other materials, may also be used as a matrix material for components such as housings and assembly templates.

The Power LED devices of the invention provide substantially greater and more stable light output than other Power LED devices. The Power LED devices of the invention concurrently provide greater brightness efficiency and longer lifetime, although operating at significantly higher temperatures and power emission levels than conventional LED devices.

Hence, the present invention concerns a Power LED device, comprising: an LED and a reflector;

wherein the reflector comprises (i) at least 50% by weight of at least one aromatic polyester having at least 80 mol % of aromatic monomer units or (ii) at least 30% by weight of at least one wholly aromatic polyester.

The Power LED device has preferably a lumen depreciation value L₉₉ of at least 1,000 hours when driven at 150 mA.

The Power LED device is also preferably capable of emitting at least 50 lumens of light for 50,000 hours when driven at 150 mA.

The aromatic polyester and the wholly aromatic polyester comprise preferably at least one of the following structural units:
structural units (I) derived from hydroquinone,

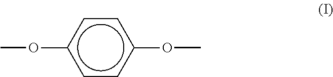

structural units (II) derived from 4,4′-biphenol,

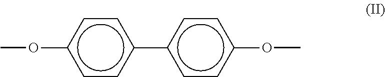

structural units (III) derived from terephthalic acid,

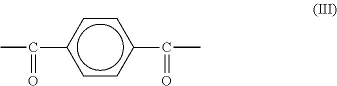

structural units (V) derived from p-hydroxybenzoic acid,

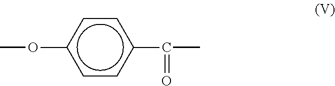

and, optionally in addition, structural units (IV) derived from isophthalic acid;

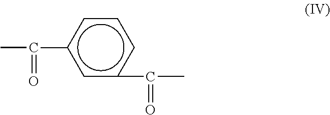

More preferably, the aromatic polyester and the wholly aromatic polyester comprise the structural units (I), (II), (III) and (V).

Good results are obtained notably with aromatic polyesters and wholly aromatic polyesters comprising polymerized structural units derived from p-hydroxybenzoic acid, terephthalic acid, hydroquinone and 4,4′-biphenol, and optionally isophthalic acid, wherein the structural units derived from p-hydroxybenzoic acid are present in an amount of 40-80 mole %, the structural units derived from terephthalic and isophthalic acid are present in an amount of 10-30 mole %, and the structural units derived from hydroquinone and 4,4′-biphenol are present in an amount of 10-30 mole %, wherein mole % is based on the total number of moles of polymerized monomer units derived from p-hydroxybenzoic acid, terephthalic acid, hydroquinone, 4,4′-biphenol and isophthalic acid. In said aromatic polyesters and wholly aromatic polyesters, the molar ratio of the structural units derived from hydroquinone to the structural units derived from 4,4′-biphenol is advantageously from 0.1 to 1.5.

In a preferred embodiment, the reflector comprises the wholly aromatic polyester, and the wholly aromatic polyester is obtained by a process comprising: forming an initial monomer mixture comprising one or more aromatic diols and one or more aromatic carboxylic acids; wherein the number of hydroxy units of the aromatic diols is substantially the same as the number of moles of carboxylic acid groups of the aromatic carboxylic acids (wherein “substantially” corresponds typically to a ratio of these two numbers ranging from about 0.95 to 1.05, often from about 0.99 to about 1.01);

reacting the initial monomer mixture to form the wholly aromatic polyester.

In this preferred embodiment, the process for making the wholly aromatic polyester further comprises:

mixing the initial monomer mixture with an acylating agent to form an acylation mixture;
wherein the reacting comprises:
heating the acylation mixture to a first temperature to form an acylated monomer mixture; and
heating the acylated monomer mixture to a second temperature to carry out solid state polycondensation of the acylated monomer mixture.

The reflector may consist of at least one of the aromatic polyester and the wholly aromatic polyester. Alternatively, the reflector may consist of a polymer composition comprising at least one of the aromatic polyester and the wholly aromatic polyester, and at least one additive. In preferred embodiments, the reflector consists of a polymer composition comprising at least one of the aromatic polyester and the wholly aromatic polyester, and at least one optical brightener.

The Power LED may further comprise a heat sink in direct contact with the reflector. The case being, the heat sink comprises preferably at least 50% by weight based on the total weight of the heat sink of one or more of the aromatic polyester and the wholly aromatic polyester. Alternatively or complementarily, the reflector may further comprise a heat sink integral with the base of the reflector. The Power LED device may further comprise a heat sink in thermal contact with the exterior surface of the reflector and made of at least one metal.

The reflector may have a base, an open top and walls that form a reflector cavity, wherein the LED is positioned on the interior surface of the base of the reflector inside the reflector cavity, and wherein the Power LED device further comprises a cured transparent resin covering the LED and at least partially filling the cavity of the reflector. The LED may be in direct contact with the base of the reflector. The Power LED device may further comprise an anode lead and a cathode lead connected to the LED.

### BRIEF DESCRIPTION OF THE DRAWING

FIG. 1 shows a high level diagram of a Power LED device of the invention.

### DETAILED DESCRIPTION OF THE PREFERRED EMBODIMENTS

Additional aspects and other features of the present invention will be set forth in part in the description that follows and in part will become apparent to those having ordinary skill in the art upon examination of the following or may be learned from the practice of the present invention. The advantages of the present invention may be realized and obtained as particularly pointed out in the appended claims. As will be realized, the present invention is capable of other and different embodiments, and its several details are capable of modifications in various obvious respects, all without departing from the present invention. The description is to be regarded as illustrative in nature, and not as restrictive.

Aromatic polyesters and wholly aromatic polyesters (usually LCPs) are shown herein to provide excellent thermal/physical stability and light reflection performance when used as components for Power LED devices. The invention includes Power LED devices having improved light emission properties and that include one or more components made from an aromatic PE (usually, an LCP) or a wholly aromatic PE (also usually, an LCP), and/or from a composition containing at least one of the aromatic PE and the wholly aromatic PE.

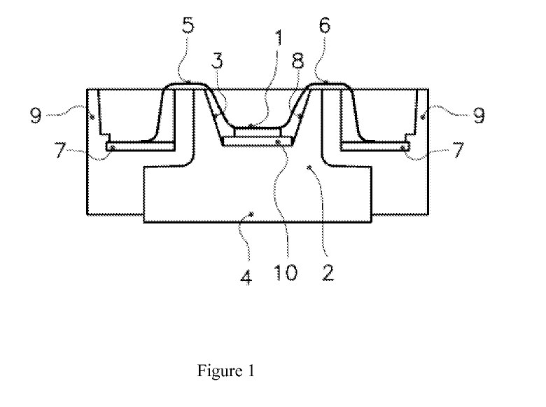

One aspect of the invention includes Power LED devices that contain one or more components comprising an aromatic PE and/or a wholly aromatic PE (usually, LCPs). An embodiment of the Power LED device of the invention is shown in a high level diagram as FIG. 1. The LED of the Power LED device is identified by reference numeral (1). The LED (1) is positioned inside component (2) of the Power LED device. While the Power LED device shown in FIG. 1 includes a single LED, in other embodiments of the invention additional LEDs may be present in the same or a different orientation. Component (2) may include both separate reflector (3) and heat sink (4) features or may combine reflector (3) and heat sink (4) features as a single component.

In embodiments of the invention where, for example, the LED junction temperature and the LED driving amperage are rather low, component (2) may consist of a reflector without a base of greater mass than the mass of the reflector. The reflector mass is calculated based on the amount of material extending upwards from the both of the reflector assembly where any thickness of the base greater than the thickest part of the reflector is considered to be a thermal sink.

In certain particular embodiments of the invention the reflector may be absent or may be made of a material that does neither contain the aromatic polyester nor the wholly aromatic polyester. When the reflector of the Power LED devices of the invention are made from such a material, at least one other component, preferably the heat sink, must be comprise the aromatic PE and/or the wholly aromatic PE (usually, LCPs). Preferably the Power LED reflector of the invention is a part of the Power LED device of the invention.

The reflector (3) of FIG. 1 serves to concentrate and direct light generated by the LED so that the light is directed in a beam-like or flood-like fashion away from the Power LED device. Light may be emitted from the LED of the Power LED device in many patterns including bat-wing, Lambertian and side-emission. The reflector permits the light output from the LED to be collected, concentrated and/or directed in a preferred orientation. The Power LED device may have a display or emission orientation of any of a top view, a side view, a transmitted view and/or an oblique view.

In component (2) of FIG. 1 the reflector has raised walls and forms a depression and/or cavity. The depression and walls may be any shape. In some embodiments the reflector is flat and has only a base and no walls. Preferably the reflector (3) has circular walls extending from the base in a cylindrical or tube-like manner with an open top. The walls may be angular walls, straight walls, parabolic in shape, conical in shape, pyramidal in shape, elliptical in shape, symmetrical, unsymmetrical and/or a combination of geometries. Preferably, the LED is positioned in the cavity or depression of the reflector so that no portion of the LED is higher than the uppermost portion of the walls of the reflector. The LED is preferably positioned so that it is at least one and preferably at least five LED heights below the upper limit of the walls of the reflector. An LED height is the vertical height of the LED as it is lies flat in a horizontally plane on the bottom of the reflector.

Component (3) represents a reflector which may be integral with a heat sink (4). The heat sink serves to conduct and transfer heat energy away from the LED of the Power LED device. Heat resulting from the operation of the LED, e.g., heat generated by the junction temperature of the Power LED device, is preferably quickly withdrawn from the LED assembly and dissipated. The heat sink serves the purpose of capturing heat from the LED (i.e., heat from a PN junction of the LED and/or heat from the wire connections to the LED junctions) and transferring the heat energy away from the LED so that it is released and dissipated outside the electronic device in which the LED is positioned or mounted.

In some embodiments of the invention the reflector of the Power LED device is manufactured separately from the other components, for example, by injection molding. Thus the reflector (e.g., the LED reflector described below) may be added to one or more components such as a Power LED housing to form a Power LED device. The reflector can be separately mounted in direct thermal contact, indirect thermal contact, or thermally insulated from the other components of the Power LED devices of the invention.

Like the reflector, the heat sink (4) preferably consists of the wholly aromatic PE and/or the aromatic PE (usually, LCPs). In one embodiment of the invention the reflector and heat sink are made by injection molding and represent a single injection molded part. The heat sink may be of any size relative to the PLED. Larger heat sinks capable of capturing and conducting a greater amount of heat away from the PLED are preferred. The absence of a heat sink may lead to overheating and poor heat conduction away from the PLED device. In embodiments of the PLED devices of the invention the heat sink preferably has a mass of at least 10 times the mass of the LED. Even more preferably the heat sink has a mass of at least 20, 30, 40, 50, 60, 70, 80, 90, and 100 times or more than mass of the LED.

The heat sink (4) may be contacted with one or more additional thermally conducting components that serve to transfer heat from the heat sink to any area of the Power LED assembly or lighting device such that the heat escapes the Power LED assembly. For example, a substrate in direct or thermal contact with the bottom surface of the heat sink may function to transfer heat away from the Power LED device. The substrate may include a printed circuit board or a metallic and/or thermoplastic or thermoset material that is thermally conducting and at least partially electrically insulating.

Preferably, the LED (1) is in direct and continuous contact with the heat sink (4) and/or the bottom portion of the reflector (3). Continuous and direct horizontal contact between the LED and a planar surface of the reflector and/or the heat sink is preferred. In other embodiments, a dielectric layer or connecting layer (10) is present between the LED (1) and the base portion of the reflector (3) which may also be a portion of the heat sink (4).

Instead of a using a connecting layer to hold the LED (1) in place on component (2) on the base of the reflector (3), the LED may alternately be fitted into the reflector and/or the heat sink by a friction connection. For example, the LED may be pressed into a depression embossed, engraved or molded into the base of the reflector or the top of the heat sink such that the bottom surface of the LED is in direct contact with the surface of the reflector and/or the heat sink that is made from at least one of the aromatic PE (usually, an LCP) and the wholly aromatic PE (usually, an LCP) and is held in place by frictional forces occurring through contact between the vertical surfaces of the LED (e.g., the side surfaces of the LED) and vertical surfaces present in the depression into which the LED is mounted. In another embodiment, the LED is in direct and continuous contact with the base of the reflector (3) or the top surface of a heat sink (4) by fitting the LED in a depression located therein and further by adhering the LED to the reflector and/or heat sink by applying an adhesive material to the vertical walls of the LED and the vertical walls of any depression made in the base of the reflector and/or top surface of the heat sink such that no layer interrupts the direct and continuous contact between the horizontal surfaces of the LED and the reflector and/or heat sink.

In other embodiments, a dielectric or connecting layer (10) is present between the LED (1) and the reflector and/or heat sink. The dielectric (10) layer may function as a means of connecting the LED (1) to the reflector (3) and/or heat sink (4). Alternately, the dielectric layer (10) may serve to electrically insulate the LED from the reflector and/or the heat sink.

The LED (1) is connected to a power source through cathode and anode connections. The cathode (5) and anode (6) connections may be formed by wires that are bonded to anode and/or cathode connections on the LED (1) and connect the LED to, for example, a lead frame (7). It is not necessary that the anode and/or cathode connections are formed from wires. In other embodiments of the invention the anode and/or cathode connections may be integral with the reflector and/or the heat sink. For example, the reflector and/or heat sink may be injection molded in a manner such that wires (5) and (6) are already present therein. The connecting wires (5) and (6) may directly contact the LED from the bottom surface which is in direct and continuous contact with any of the bottom surface of the reflector and/or an intermediate connecting layer (10). In this manner, the wire bonding does not interfere with light emitted from the LED.

Other components may be present in the Power LED device of the invention. A clear or frosted lens that is colorless or colored may be present covering the LED and optionally sealing the cavity formed by the reflector or covering at least a portion or the entire top surface of the Power LED device. The lens functions to protect the LED from the elements and/or to focus, color, collimate and/or direct the light emitted from the LED. A lens may be formed from any type of transparent material including glass and thermoplastic such as acrylic, polyolefinic, silicone and/or polycarbonate materials. Alternately, the LED may be potted in a thermosetting material that is injected into the reflector depression and hardens to cover both the LED and at least partially fills the cavity formed by the reflector walls. Thermosetting materials such as epoxies, silicones and acrylics often show poor thermal conduction. Therefore, the LED device may still require the presence of a heat sink made from at least one of the aromatic PE (usually, an LCP) and the wholly aromatic PE (also usually, an LCP).

The walls (8) of the reflector may be coated with one or more reflective materials. For example, the walls of the reflector may be coated with a metallic material such as aluminum. The purpose of such metalizing is to improve the amount of light that is usably emitted from the PLED device. Other lighting effects may be achieved by treating the walls of the reflector in other ways. For example, the walls of the reflector may be imparted with roughness or other surface finish to reduce effects of glare and/or to color the light emitted from the PLED device. In other embodiments that walls of the reflector are covered with a colored with a dyed or pigmented material. The colored covering may be a coating that is integral with the reflector or a separate part such as an insert. The colored material may be used to change the color or color characteristics of the light emitted from the PLED device.

The aforementioned components of the PLED device may be mounted in a housing and or assembly package (9) which functions to hold any combination of the reflector (3), heat sink (4), and LED (1) for mounting as, for example, a surface mount device. The package (9) may be made from a thermoplastic material that is the same as the thermoplastic material used for making the reflector (3) and/or the heat sink (4). Intimate contact between the packaging (9) and the heat sink (4) and/or the reflector (3) further improves heat dissipation from the LED. In some embodiments of the invention the packaging (9) has significantly lower thermal conductivity in comparison to the heat sink and/or reflector (3). Providing a packaging having lower heat conductivity provides a surface mount device which is connected to a substrate such as a printed circuit board (PCB) in a manner such that minimal amounts of heat are transferred directly to the substrate.

In the same PLED device the reflector (3) and the heat sink (4) may comprise different or the same materials including the aromatic PE and/or the wholly aromatic PE (usually LCPs). The use of different materials in the reflector and heat sink permits the selection of desirable properties for different components of the PLED device. For example, high heat resistance is desirable in the reflector. High heat resistance reduces thermal degradation and discoloration of the reflector and thus permits a longer LED lifetime without color degradation or color shift. This may be especially important in Power LED devices.

The PLED device of the invention may be described by the power requirements of the LED. In particular, power LEDs operating at currents of greater than 150 mA are included in the invention. Operating current and voltage are specified by the maker of the LED and measured according to IES LM-79-08 and IES LM-80-08.

The Power LED device of the invention may be described by the degree to which the Power LED maintains its initial light output after operation at a fixed drive amperage. The Power LED device of the invention preferably retains 50% or more of its initial light output after 50,000 hours or more of use. The loss of light output is measured at the drive amperage specified by the maker of the Power LED, for example at 150 mA. Light output in lumens is measured according to IES LM-79-08. When determining light output loss or depreciation, the same conditions are used when measuring initial light output and final light output.

In other embodiments, the Power LED device of the invention maintains 60%, 65%, 70%, 75%, 80%, 85%, 90%, 95% or 99% of its initial light output in lumens after 50,000 hours of operation. Initial light output is the number of lumens emitted from the Power LED device after a burn-in period of 100 hours. Preferably, the light output of the Power LED device of the invention is spectrally the same or the same within limits of human visual perception after 50,000 hours of operation at the design amperage as the initial light output of the virgin Power LED. One method of measuring the brightness and color of light produced by the LED is according to Y. Zong and Y. Ohno, “New practical method for measurement of high-power LEDs. Proc.,” CIE Expert Symposium on Advances in Photometry and Colorimetry, CIE x033:2008, pp. 102-106 (2008), incorporated herein by reference in its entirety. Preferably, the IESNA LM-79, C78.377-2008 Approved Method for the Electrical and Photometric Measurements of Solid-State Lighting Products, incorporated herein by reference in its entirety, is used for testing the Power LED devices of the invention for light output (lumens), energy efficiency (lumens per watt) and chromaticity. Light depreciation in the Power LED devices is measured according to LM-80, “IESNA Approved Method for Measuring Lumen Depreciation of LED Light Sources”, incorporated herein by reference in its entirety.

The Power LED device may also be described by time required to reach a specified light output. Lumen depreciation values reflect the overall performance of a Power LED over its life. As Power LED's are operated, their lumen output decreases with time. Lumen depreciation is the amount of time a Power LED is operated before a particular degree of lumen depreciation is reached. For example, a lumen depreciation value of 99% (i.e., L₉₉) corresponds to the time needed to operate the Power LED device at its specified operating current and voltage before the device loses 1% of its initial light output. Preferably, the PLED device of the invention has an L₉₉ value of at least 1,000 hours at a drive amperage of 150 mA. In other preferred embodiments the L₉₉ at 150 mA is of at least 1,500 hours, at least 2,000 hours, at least 3,000 hours, at least 4,000 hours, at least 5,000 hours, at least 6,000, at least 7,000 hours, at least 8,000, at least 9,000 hours or at least 10,000 hours. In still other preferred embodiments, the PLED device of the invention has an L₉₉ value of at least 1,000 hours at a drive amperage of 200 mA, 250 mA, 300 mA, 350 mA, 400 mA, 500 mA, 600 mA, 700 mA, 800 mA, 900 mA, 1,000 mA, 1,500 mA, 2,000 mA or 5,000 mA. In still other preferred embodiments, the PLED device of the invention has an L₉₉ value of at least 1,000 hours at a drive amperage of at least 150 mA, at least 200 mA, at least 300 mA, at least 400 mA, at least 500 mA or at least 1,000 mA; more preferably, the PLED device of the invention has an L₉₉ value of at least 2,000 hours at a drive amperage of at least 150 mA, at least 200 mA, at least 300 mA, at least 400 mA, at least 500 mA or at least 1,000 mA; still more preferably, the PLED device of the invention has an L₉₉ value of at least 5,000 hours at a drive amperage of at least 150 mA, at least 200 mA, at least 300 mA, at least 400 mA, at least 500 mA or at least 1,000 mA; the most preferably, the PLED device of the invention has an L₉₉ value of at least 10,000 hours at a drive amperage of at least 150 mA, at least 200 mA, at least 300 mA, at least 400 mA, at least 500 mA or at least 1,000 mA. In still other embodiments of the invention the Power LED device may have L₉₀ values at the drive current specified by the maker of the LED of at least 10,000 hours, at specified drive currents of 150 mA, 200 mA, 250 mA, 300 mA, 350 mA, 400 mA, 500 mA, 600 mA, 700 mA, 800 mA, 900 mA, 1,000 mA, 1,500 mA, 2,000 mA or 5,000 mA. In still other embodiments of the invention the Power LED device may have L₉₈, L₉₇, L₉₆, L₉₅, L₉₄, L₉₃, L₉₂, L₉₁ or L₉₀ values at the drive current specified by the maker of the LED of at least 1000, at least 1,500, at least 2,000, at least 3,000, at least 4,000, at least 5,000, at least 6,000, at least 7,000, at least 8,000, at least 9,000 or at least 10,000 hours, at specified drive currents of at least 150 mA, at least 200 mA, at least 250 mA, at least 300 mA, at least 350 mA, at least 400 mA, at least 500 mA, at least 600 mA, at least 700 mA, at least 800 mA, at least 900 mA, or at least 1,000 mA.

The Power LED of the invention may also be distinguished from ordinary LED devices from the thickness of the reflector. The thickness of a Power LED reflector is greater than the thickness of a conventional reflector. The thickness of a reflector is measured at a point immediately below the location where the LED chip is positioned. The reflector thickness includes only the thickness of the aromatic or wholly aromatic material from which the reflector is molded or otherwise fashioned. Layers or any thickness component representing the lead frame and or any dielectric layer made of material that is different from the material from which the reflector is formed is not included in the measurement of reflector thickness. The reflector thickness may have more than one component. For example a reflector having walls will have a reflector wall thickness. The wall thickness can be measured at the bottom of the wall where it joins the reflector bottom or at the top of the wall at the opening of the reflector cavity.

Preferably the reflector has a thickness of from 5 to 50 mm, more preferably from 6 to 45 mm, 7 to 40 mm, 8 to 35 mm, 9 to 30 mm, 10 to 25 mm, 11 to 20 mm, 12 to 15 mm, or 13 to 14 mm. Preferably the reflector thickness is measured independently of the thickness of any heat sink whether integral with the reflector or present as a separate component fastened to the reflector.

As shown in FIG. 1, and as explained above, PLED devices typically include a reflector for directing light emitted from a LED in a desired orientation. The reflector also serves to collect the light emitted from an LED such that the majority of emitted light can be used for lighting purposes. The light reflected from a reflector surface is affected by the color of the surface on which the light is reflected. If a reflector of a PLED device changes color over time, the light reflected from the PLED device will likewise change color.

Conventional LED reflectors are made from thermoplastic materials that degrade on exposure to high heat or radiation. Under the higher stress conditions encountered in a Power LED device such materials may undergo greater degradation on shorter operation. This degradation can affect the color characteristics of the light emitted by the Power LED device.

Preferably the Power LED device provides a white light with a spectral output having a color temperature of from 2,500 K to 6,500 K. Preferably, the Power LED has a color temperature of about 3,200 K and may be used as a replacement for conventional incandescent lighting devices such as light bulbs. Color temperature may be varied or customized by, for example, changing the color of the reflector of the Power LED device. In other embodiments the color temperature of the Power LED device is 2000, 2010, 2020, 2050, 2080, 2200, 2600, 2800, 3000, 3500, 4000, 4500, 5000, 5500, 6000 K with all ranges and subranges between the stated values expressly included herein, e.g., 3000, 3010, 3020, 3030, 3040, 3050, 3060, 3065, 3066, 3067, 3068, 3069, and 3070. Chromaticity values of the PLEDs of the invention are preferably within the correlated color temperature categories defined in ANSI_NEMA_ANSLA C78.377-2008 (American National Standard for electric lamps—Specifications for the Chromaticity of Solid State Lighting Products), incorporated herein by reference in its entirety.

The whiteness of light produced by the Power LED device of the invention may be measured according to CIE standard illuminant D65. Relative measurements of the light produced by the Power LED device with CIE standard white light permits an evaluation of color change occurring in the Power LED device over time and/or under certain operating conditions. In some embodiments the difference between the whiteness of light produced by the Power LED device in comparison with CIE standard illuminant D65 as shown in the L*, a* and b* values is less than 50%, more preferably less than 40%, 35%, 30%, 20%, 25%, 20%, 15%, 10%, or 5% absolute.

The PLEDs of the invention exhibit good color stability. The use of certain polymers such as the aromatic PE and wholly aromatic PE (usually, LCPs) mentioned herein allows the devices to show greater resistance towards thermal and/or radiation degradation. Because the materials used to make the reflectors of the PLED devices have good color stability, the reflectors made therefrom likewise show good color stability.

The color stability of the PLED reflectors of the invention can be measured as a function of the change in the ΔE* of the reflector as a function of time and/or the change in the reflectance of the reflector as a function of time. For example, in preferable embodiments the ΔE* of the reflector changes by no more than 1% based on the initial ΔE* of the reflector. The initial ΔE* is the ΔE* for the reflector measured before an LED is installed on the reflector and/or before the PLED device is operated. The ΔE* is measured directly on the surface of the reflector at the same location on the reflector to obtain the initial and aged ΔE* values. In preferred embodiments the initial ΔE* does not change more than 1% after operation at 150 mA or greater (i.e., the specified drive amperage of the PLED device) after 1,000 hours of operation. In other embodiments the initial ΔE* does not change more than 2%, 3%, 4%, 5%, 6%, 7%, 8%, 9%, 10%, 15%, 20%, 25%, or 30% after 1,000 hours of operation. In further embodiments the aforementioned changes in initial ΔE* do not occur after 2,000, 3,000, 4,000, 5,000, 6,000, 7,000, 8,000, 9,000, or 10,000 hours of operation under the conditions specified by the maker of the PLED for operating the PLED device.

As described above, the color and/or light stability of the PLED reflectors of the invention can be measured as a function of the change of the initial reflectance of the reflector. The change in reflectance is determined by measuring the initial reflectance of the reflector before the PLED device has been operated. The reflectance is then measured after the PLED device has been operated for a period of time. Reflectance may be measured at one or more particular wavelengths of light. The change in reflectance relative to the initial reflectance is calculated as a value in %. Reflectance can be measured by using, for example, a BYK-Gardner Color-Sphere instrument over a wavelength range of 400 to 700 nm with a 20-nm interval. Reflectance is measured following ASTM E308-06 (incorporated herein by reference in its entirety) using diffuse illumination (D65) and 8° observation (d/8) with Specular Component Included, with no bandpass correction. It is preferred that the measurement is carried out with 30 mm and 36 mm measurement and illumination areas, respectively. However, reflectance can also be measured at particular locations on the reflector.

In preferred embodiments the initial light reflected from the PLED reflectors of the invention does not change by more than 1% when measured at 460 nm and 760 nm when the PLED is operated at the drive amperage specified by its maker for a period of 1,000 hours. In preferred embodiments the initial reflectance does not change more than 1% after operation at 150 mA or greater (i.e., the specified drive amperage of the PLED device) after 1,000 hours of operation. In other embodiments the initial reflectance does not change more than 2%, 3%, 4%, 5%, 6%, 7%, 8%, 9%, 10%, 15%, 20%, 25%, or 30% after 1,000 hours of operation. In further embodiments the aforementioned changes in initial reflectance do not occur after 2,000, 3,000, 4,000, 5,000, 6,000, 7,000, 8,000, 9,000, or 10,000 hours of operation under the conditions specified by the maker of the PLED for operating the PLED device, e.g., 150, 200, 250, 300, 350, 400, 450, 500, 550, 600, 650, 700, 750, 800, 850, 900, 950, or 1,000 mA with all values, ranges and subranges within the stated values expressly included herein.

The reflectors of the PLED devices are preferably made from a composition comprising the aromatic PE and/or the wholly aromatic PE (usually LCPs). In certain preferred embodiments, the composition consists of the aromatic PE and/or the wholly aromatic PE (usually LCPs). In some preferred embodiments of the invention the reflector is molded from a thermoplastic composition wherein the only thermoplastic polymer is the aromatic PE and/or the wholly aromatic PE (usually LCPs) but the composition may otherwise contain any amount of inorganic filler and/or pigment. In other preferred embodiments of the invention the reflector is made from a composition comprising one or more thermoplastic components which comprises at least 30% by weight of the wholly aromatic PE (usually, an LCP), more preferably at least 40%, 50%, 60%, 70%, 80%, 90%, 95%, 98%, 99% of the wholly aromatic PE based on the total weight of the reflector. In other embodiments of the invention the reflector is made from a composition comprising one or more thermoplastic components which comprises at least 50% by weight of the aromatic PE (usually, an LCP), more preferably at least 60%, at least 70%, at least 80%, at least 90%, at least 95%, at least 98%, at least 99% of the aromatic PE based on the total weight of the reflector.

The aromatic and wholly aromatic PEs (usually LCPs) have improved color properties in comparison to conventional LCPs. Improved color properties include lower ΔE (Delta E) and lower yellowness index values measured on finely ground aromatic and wholly aromatic PEs, e.g. finely ground wholly aromatic LCPs, using a CIE scale, reference tiles and calculations of Delta E known to those skilled in the art. A resin having a relatively lower ΔE is indicative of improved whiteness. Preferably the aromatic PEs and the wholly aromatic PEs, in particular the wholly aromatic LCPs, of the invention have a ΔE of less than 25, more preferably less than 24, 23, 22, 21, or 20 or 19, 18, 17, 16, 15, 14, 13, 12, 11, or 10 it is especially preferred that the aromatic PEs and the wholly aromatic PEs, in particular the wholly aromatic LCPs, of the invention has a ΔE of less than 22. Preferably, the aromatic PEs and wholly aromatic PEs (usually, LCPs) of the invention have a yellowness index of less than 25, preferably less than 24, 23, 22, 21, 20, 19, 18, 17, 16, 15, 14, 13, 12, 11, or 10; it is especially preferred that the aromatic PEs and wholly aromatic PEs (usually, LCPs) have a yellowness index of less than 20, more preferably 10-20. YI value and L value are values obtained by measuring a test piece of a polyester resin with the use of a color difference meter according to ASTM D1925.

Color of compounded resin is measured on molded disks, 2.5″ diameter and 0.040″ thick according to ASTM E308-06 using a BYK-Gardner Color-Sphere instrument with wavelength range of 400 to 700 nm and interval of 20 nm, no bandpass correction, observation angle of 10° (CIE 1964 supplementary standard observer), D65 illumination and 30 mm and 36 mm measurement and illumination areas, respectively. The color difference for the disks compared to white reference tile is calculated using the CIELAB ΔE* (Delta E) equation. The white reference tile (S/N 870007) values for L*, a* and b* values were 98.86±0.01, −0.17±0.01 and 0.38±0.01, respectively.

The BYK-Gardner Color-Sphere instrument is used to measure percent reflectance of the disks over the wavelength range of 400 to 700 nm with a 20-nm interval. Reflectance was measured following ASTM E308-06 using diffuse illumination (D65) and 8° observation (d/8) with Specular Component Included, with no bandpass correction and with 30 mm and 36 mm measurement and illumination areas, respectively.

The light output in lumens of the Power LED device is variable and, in one embodiment, depends on drive amperage. Higher drive amperage may result in higher light output. Preferably, the Power LED is suitable for being operated at a drive amperage of at least 150 mA. Power LEDs suitable for being operated at drive amperages of at least 300 mA, at least 500 mA, at least 1,000 mA, at least 1,500 mA or at least 2,000 mA are included in the invention. As herein used, the terms “suitable for” imply typically that the specified drive amperages correspond to the nominal conditions at which the Power LED is operated, as commonly determined by the LED manufacturer; on the other hand, a Power LED that would have to be “overpowered” to provide sufficient light output should in general not be considered as a suitable one, as the higher drive amperage would cause irremediably some damage to the Power LED and/or shorten its lifetime by accelerating its light output loss or depreciation over time. The Power LED device of the invention preferably emits over 100 lumens when driven at 1,000 mA. The power performance of the Power LED may also be expressed in terms of wattage where an output of 1 Watt or greater is preferred. Light output can be further varied by adjusting the drive amperage of the LED with greater drive amperage generally corresponding to higher junction temperatures and an increase in light output measured in lumens. The relatively higher drive amperage and higher junction temperatures of Power LED devices in comparison to conventional LED devices generates relatively more heat.

Preferably, a heat sink is used to remove heat generated during operation of the LED device especially when operating at high junction temperatures or high operating amperage. In some embodiments, including embodiments where a Power LED device is driven at relatively low amperage (e.g., from 150 to 500 mA) and emits low lumens or has a low junction temperature, the Power LED device of the invention, i.e., a Power LED device containing one or more components made from the at least one of the aromatic PE (usually, an LCP) and the wholly aromatic PE (also usually, an LCP), provides heat conduction efficiency and heat resistance properties that permit the use of high amperage (e.g., 150 mA or greater) with a separate heat sink. The Power LED device of the invention may operate effectively to produce white light at drive amperages of from 150 to 1,000 mA and higher, and junction temperatures of from 100° C. to 200° C. or higher, preferably from 130° C. to 180° C. or about 150° C.

The aromatic PE and/or the wholly aromatic PE (usually LCPs) included in the Power LED devices of the invention function to remove heat by thermal conduction such that heat is dissipated to the environment or conducted to an underlying substrate and/or heat sink for later dissipation. The heat sink can remove heat from the LED device without substantially impacting light quality or color.

Another aspect of the invention is an LED reflector that can be used for Power LED applications. The LED reflector of the invention is at least partially made from the aromatic PE and/or the wholly aromatic PE (usually LCPs). The LED reflector of the invention may be the reflector (3) of the PLED device shown in FIG. 1 or it may be an article separate from any PLED device.

Either the LED reflector contains at least 50% by weight of the aromatic PE (usually, an LCP) based on the total weight of the reflector, or the LED reflector contains at least 30% by weight of the wholly aromatic PE (usually, an LCP) based on the total weight of the reflector, or both. The LED reflector may contain at least 40%, at least 50%, at least 60%, at least 70%, at least 80%, at least 90%, at least 95%, at least 96%, at least 97%, at least 98%, at least 99%, or at least 99.5% by weight of the wholly aromatic PE (usually, an LCP), based on the total weight of the reflector. The LED reflector may also contain at least 60%, at least 70%, at least 80%, at least 90%, at least 95%, at least 96%, at least 97%, at least 98%, at least 99%, or at least 99.5% by weight of the aromatic PE (usually, an LCP), based on the total weight of the reflector. The LED reflector may contain a combination of the wholly aromatic PE and of the aromatic PE in any of the above specified amounts for these two polymers, as long as their cumulated amount does not exceed 100%.

In other embodiments the LED reflector preferably consists of, or consists essentially of, the aromatic PE and/or the wholly aromatic PE (usually LCPs).

In other embodiments the LED reflector is made from a composition comprising the aromatic PE and/or the wholly aromatic PE (usually LCPs) and one or more additional materials. The additional materials preferably function to (1) reduce the electrical conductivity of the reflector, (2) improve thermal conductivity of the reflector, (3) color the material, and/or (4) stabilize the material against changes in color and/or physical properties. Thermal conductivity may be improved by including fillers such as fibers of inorganic material, particulate inorganic fillers and other materials that are electrically non-conducting but serve to transmit heat through the wholly aromatic polymer matrix. The composition comprising the aromatic PE and/or the wholly aromatic PE is described further below.

In embodiments of the PLED reflector the walls of the reflector may be coated with one or more reflective materials. For example, the walls of the reflector may be coated with a metallic material such as aluminum. The purpose of such metalizing is to improve the amount of light that is usably emitted from the PLED device. Other lighting effects may be achieved by treating the walls of the reflector in other ways. For example, the walls of the reflector may be imparted with roughness, color or other surface finish to reduce effects of glare. The PLED reflectors may have the features of the reflector of the PLED device described herein.

The conduction of heat away from a PLED device may affect the intensity and brightness of the light produced by the LED of the device. While LEDs do not themselves produce heat, the electrical junctions forming the LED and/or the electrical junctions formed by bonding the LED to one or more sources of electrical energy may release substantial amounts of heat when the LED is electrically driven.

The intensity, color characteristics and brightness of the light produced by an LED may be influenced by the temperature of the LED. Heat generated by the electrical junctions in an LED device may significantly affect the light emission properties of the underlying LED. The ability to quickly and efficiently direct heat away from a LED provides a way to stabilize the light emission properties of the LED. The heat sink may have the features of the heat sink of the Power LED device described herein.

Thermally conducting materials such as metals that draw heat away from an LED may be used to form some of the components of a PLED device. Metallic materials are able to efficiently and quickly remove heat from an LED and thus may help to stabilize the light emission properties of the LED. The use of metallic materials in PLED devices is substantially limited by the fact that metals are both thermally and electrically conducting. The use of metallic materials as a means of conducting heat from both anode and cathode junctions of a LED is impractical because voltage leakage may occur across the metallic materials. Further, metallic materials such as copper are expensive and may not be compatible with certain flexible substrates, and may corrode when in contact with certain materials.

In embodiments of the PLED devices wherein the heat sink is made from the aromatic PE and/or the wholly aromatic PE (usually LCPs), it is preferable that the entire heat sink is made from said polymers. In other embodiments the heat sink is made from a composition that comprises the aromatic PE and/or the wholly aromatic PE (usually LCPs) and one or more additional materials. The composition used to make the heat sink portion of the Power LED device of the invention may include other materials that preferably (1) reduce the electrical conductivity of the heat sink, (2) improve thermal conductivity of the heat sink and/or (s) stabilize the heat sink against thermal degradation. Thermal conductivity may be improved by including fillers such as fibers of inorganic material, particulate inorganic fillers and other materials that are electrically non-conducting but serve to transmit heat through the PE matrix.

Preferably, the PLED reflector, the heat sink of the PLED device or both the reflector and the heat sink of the PLED device are made from only the aromatic PE and/or the wholly aromatic PE (usually LCPs) without fillers or inorganic materials. In such an embodiment, the PLED reflector, the heat sink of the PLED device or both the reflector and the heat sink of the PLED device (or other component of the PLED device) consist of the aromatic PE and/or the wholly aromatic PE (usually LCPs).

In other embodiments, the PLED reflector, the heat sink of the PLED device, or both the reflector and the heat sink of the PLED device are made from compositions that contain the aromatic PE and/or the wholly aromatic PE (usually LCPs) in addition to one or more other materials. In some embodiments such compositions contain a heat stabilizer and/or optical brightener such as an organic phosphate to further inhibit degradation of the aromatic PE and/or the wholly aromatic PE (usually LCPs). In other embodiments, the compositions do not contain any heat stabilizers and/or do not contain any optical brightener.

Certain stabilizers such as hindered amine light stabilizers (HALS) may be present in the composition. For example one or more of the group of hindered amines selected from the group consisting of bis(2,2,6,6-tetramethyl piperidin-4-yl)sebacate, bis(1,2,2,6,6-pentamethylpiperidin-4-yl )sebacate, di(1,2,2,6,6-pentamethylpiperidin-4-yl) (3,5-di-tert-butyl-4-hydroxybenzyl)butylmalonate, 4-benzoyl-2,2,6,6-tetramethylpiperidine, 4-stearyloxy-2,2,6,6-tetramethylpiperidine, 3-n-octyl-7,7,9,9-tetramethyl-1,3,8-triaza-spiro[4.5]decane-2,4-dione, tris(2,2,6,6-tetramethylpiperidin-4-yl) nitrilotriacetate, 1,2-bis(2,2,6,6-tetramethyl-3-oxopiperazin-4-yl)ethane, 2,2,4,4-tetramethyl-7-oxa-3,20-diaza-21-oxodispiro[5.1.11.2]heneicosane, polycondensation product of 2,4-dichloro-6-tert-octylamino-s-triazine and 4,4′-hexamethylenebis(amino-2,2,6,6-tetramethylpiperidine), polycondensation product of 1-(2-hydroxyethyl)-2,2,6,6-tetramethyl-4-hydroxypiperidine and succinic acid, polycondensation product of 4,4′-hexamethylenebis-(amino-2,2,6,6-tetra-methylpiperidine) and 1,2-dibromoethane, tetrakis(2,2,6,6-tetramethylpiperidin-4-yl)1,2,3,4-butanetetracarboxylate-, tetrakis(1,2,2,6,6-pentamethylpiperidin-4-yl)1,2,3,4-butanetetracarboxylate, polycondensation product of 2,4-dichloro-6-morpholino-s-triazine and 4,4′-hexamethylenebis(amino-2,2,6,6-tetramethylpiperidine), N,N′,N″,N′″-tetrakis[(4,6-bis(butyl-1,2,2,6,6-pentamethyl-piperidin-4-y-l)-amino-s-triazin-2-yl]-1,10-diamino-4,7-diazadecane, mixed [2,2,6,6-tetramethylpiperidin-4-yl/β,β,β′,β′-tetramethyl-3,9-(2,4,8,10-tetraoxaspiro[5.5]-undecane)diethyl]1,2,3,4-butanetetracarboxylate, mixed [1,2,2,6,6-pentamethyl piperidin-4-yl/β,β,β′,β′-tetramethyl-3,9-(2,4,8,10-tetraoxaspiro[5.5]-undecane)diethyl]1,2,3,4-butanetetr-acarboxylate, octamethylene bis(2,2,6,6-tetramethyl-piperidin-4-carboxylate), 4,4′-ethylenebis(2,2,6,6-tetramethylpiperazin-3-one), N-2,2,6,6-tetramethyl-piperidin-4-yl-n-dodecylsuccinimide, N-1,2,2,6,6-pentamethyl-piperidin-4-yl-n-do decylsuccinimide, N-1-acetyl-2,2,6,6-tetramethylpiperidin-4-yl-n-dodecylsuccinimide, 1-acetyl3-dodecyl-7,7,9,9-tetramethyl-1,3,8-triazaspiro[4.5]decane-2,4-di-one, di-(1-octyloxy-2,2,6,6-tetramethyl piperidin-4-yl)sebacate, di-(1-cyclohexyloxy-2,2,6,6-tetra-methylpiperidin-4-yl) succinate, 1-octyloxy-2,2,6,6-tetramethyl-4-hydroxy-piperidine, poly-{[6-tert-octylamino-s-triazin-2,4-diyl][2-(1-cyclohexyloxy-2,2,6,6-t-etramethylpiperidin-4-yl)imino-hexamethylene-[4-(1-cyclohexyloxy-2,2,6,6-tetramethylpiperidin-4-yl)imino], and 2,4,6-tris[N-(1-cyclohexyloxy-2,2,6,6-tetramethylpiperidin-4-yl)-n-butylamino]-s-triazine.

A most preferred hindered amine compound is bis(2,2,6,6-tetramethylpiperidin-4-yl)sebacate, bis(1,2,2,6,6-pentamethyl piperidin-4-yl)sebacate, di(1,2,2,6,6-pentamethylpiperidin-4-yl) (3,5-di-tert-butyl-4-hydroxybenzyl)butylmalonate, the polycondensation product of 1-(2-hydroxyethyl)-2,2,6,6-tetramethyl-4-hydroxypiperidine and succinic acid, the polycondensation product of 2,4-dichloro-6-tert-octylamino-s-triazine and 4,4′-hexamethylenebis(amino-2,2,6,6-tetramethylpiperidine), N,N′,N″,N′″-tetrakis[(4,6-bis(butyl-(1,2,2,6,6-pentamethylpiperidin-4-y-l)amino)-s-triazine-2-yl]-1,10-diamino-4,7-diazadecane. di-(1-octyloxy-2,2,6,6-tetramethylpiperidin-4-yl)sebacate, di-(1-cyclohexyloxy-2,2,6,6-tetramethylpiperidin-4-yl)succinate, 1-octyloxy-2,2,6,6-tetramethyl-4-hydroxy-piperidine, poly-{[6-tert-octylamino-s-triazin-2,4-diyl][2-(1-cyclohexyloxy-2,2,6,6-t-etramethylpiperidin-4-yl)imino-hexamethylene-[4-(1-cyclohexyloxy-2,2,6,6-t-etramethylpiperidin-4-yl)imino], or 2,4,6-tris[N-(1-cyclohexyloxy-2,2,6,6-tetramethylpiperidin-4-yl)-n-butylamino]-s-triazine.

The composition can additionally contain one or more other UV absorbers selected from the group consisting of s-triazines, oxanilides, hydroxybenzophenones, benzoates and α-cyanoacrylates.

Thermal stabilizers may be included in the composition. The thermal stabilizers may be one or more selected from, for example, monophenols such as, for example, 2,6-di-tert-butyl-4-methylphenol, 2-tert-butyl-4,6-dimethylphenol, 2,6-di-tert-butyl-4-ethylphenol, 2,6-di-tert-butyl-4-n-butylphenol, 2,6-di-tert-butyl-4-isobutylphenol, 2,6-dicyclopentyl-4-methylphenol, 2-(α-methylcyclohexyl)-4,6-dimethylphenol, 2,6-dioctadecyl-4-methylphenol, 2,4,6-tricyclohexcylphenol, 2,6-di-tert-butyl-4-methoxymethylphenol, 2,6-dinonyl-4-methylphenol, 2,4-dimethyl-6-(1′-methyl-undec-1′-yl)phenol, 2,4-dimethyl-6-(1′-methylheptadecyl-1′-yl)phenol, 2,4-dimethyl-6-(1′-methyl-tridec-1′-yl)phenol, and mixtures thereof; alkylthiomethylphenols, for example, 2,4-dioctylthiomethyl-6-tert-butylphenol, 2,4-dioctylthiomethyl-6-methylphenol, 2,4-dioctylthiomethyl-6-ethylphenol, 2,6-didodecylthiomethyl-4-nonylphenol; hydroquinone and alkylated hydroquinones, for example, 2,6-di-tert-butyl-4-methoxyphenol, 2,5-di-tert-butylhydroquinone, 2,5-di-tert-amylhydroquinone, 2,6-diphenyl-4-octadecyloxyphenol, 2,6-di-tert-butyl-hydroquinone, 2,5-di-tert-butyl-4-hydroxyanisole, 3,5-di-tert-butyl-4-hydroxyanisole, 3,5-di-tert-butyl-4-hydroxyphenyl stearate, and bis-(3,5-di-tert-butyl-4-hydroxyphenyl)adipate; cumarone derivatives, for example, α-tocopherol, β-tocopherol, γ-tocopherol, γ-tocopherol, and mixtures thereof; hydroxylated thiodiphenylethers, for example, 2,2′-thiobis(6-tert-butyl-4-methylphenol), 2,2′-thiobis(4-octylphenol), 4,4′-thiobis(6-tert-butyl-3-methylphenol),4,4′-thiobis(6-tert-butyl-2-methylphenol), 4,4′-thio-bis(3,6-di-sec-amylphenol), 4,4′-bis-(2,6-dimethyl-4-hydroxyphenyl)disulphide; alkylidene bisphenols, for example, 2,2′-methylenebis(6-tert-butyl-4-methylphenol), 2,2′-methylenebis(6-tert-butyl-4-ethylphenol), 2,2′-methylenebis[4-methyl-6-(α-methylcyclohexyl)phenol], 2,2′-methylenebis(4-methyl-6-(α-methylcyclohexylphenol, 2,2′-methylenebis(6-nonyl-4-methylphenol), 2,2′-methylenebis(4,6-di-tert-butylphenol), 2,2′-ethylidenebis(4,6-di-tert-butylphenol), 2,2′-ethylidenebis(6-tert-butyl-4-isobutylphenol), 2,2′-methylidenebis[6-(α-methylbenzyl)-4-nonylphenol], 2,2′-methylidenebis[6-(α,α-dimethylbenzyl)-4-nonylphenol], 4,4′-methylidenebis(2,6-di-tert-butylphenol), 4,4′-methylidenebis(6-tert-butyl-2-methylphenol), 1,1-bis(5-tert-butyl-4-hydroxy-2-methylphenyl)butane, 2,6-bis(3-tert-butyl-5-methyl-2-hydroxybenzyl)-4-methylphenol, 1,1,3-tris(5-tert-butyl-4-hydroxy-2-methylphenyl)butane, 1,1-bis(5-tert-butyl-4-hydroxy-2-methylphenyl)-3-n-dodecylmercaptobutane, ethyleneglycolbis[3,3-bis(3′-tert-butyl-4′-hydroxyphenyl)butylate], bis(3-tert-butyl-4-hydroxy-5-methylphenyl)dicyclopentadiene, bis[2-(3′-tert-butyl-2′-hydroxy-5′-methylbenzyl)-6-tert-butyl-4-methlyphenyl]terephthalate, 1,1-bis(3,5-dimethyl-2-hydroxyphenyl)butane, 2,2-bis(3,5-di-tert-butyl-4-hydroxyphenyl)propane, 2,2-bis(5-tert-butyl-4-hydroxy-2-methylphenyl)-4-n-dodecylmercaptobutane, 1,1,5,5-tetra(5-tert-butyl-4-hydroxy-2-methylphenyl)-pentane; O-, N- and S-benzyl compounds, for example, 3,5,3′,5′-tetra-tert-butyl-4,4′-dihydroxybenzylether, octadecyl-4-hydroxy-3,5-dimethylbenzyl-mercaptoacetate, tridecyl-4-hydroxy-3,5-di-tert-butylbenzyl-mercaptoacetate, tris(3,5-di-tert-butyl-4-hydroxybenzyl)amine, bis(4-tert-butyl-3-hydroxy-2,6-dimethylbenzyl)dithiophthalate, bis(3,5-di-tert-butyl-4-hydroxybenzyl)sulphide, isooctyl-3,5-di-tert-butyl-4-hydroxybenzyl-mercaptoacetate; hydroxybenzylmaloates, for example, 2,2-bis(3,5-di-tert-butyl-4-hydroxy-5-methylbenzyl)dioctadecyl maloate, 2,2-bis(3,5-di-tert-butyl-4-hydroxybenzyl)di-dodecyl mercaptoethylmaloate, 2,2-bis(3,5-di-tert-butyl-4-hydroxybenzyl)maloatebis[4-(1,1,3,3-tetramethylbutyl)-phenyl]; a hydroxybenzyl aromatic compound, for example, 1,3,5-tris(3,5-di-tert-butyl-4-hydroxybenzyl)-2,4,6-trimethylbenzene, 1,4-bis(3,5-di-tert-butyl-4-hydroxybenzyl)-2,3,5,6-tetramethylbenzene, 2,4,6-tris(3,5-di-tert-butyl-4-hydroxybenzyl)phenol; triazine compounds, for example, 2,4-bisoctylmercapto-6-(3,5-di-tert-butyl-4-hydroxyanilino)-1,3,5-triazine, 2-octylmercapto-4,6-bis(3,5-di-tert-butyl-4-hydroxyanilino)-1,3,5-triazine, 2-octylmercapto-4,6-bis(3,5-di-tert-butyl-4-hydroxyphenoxy)-1,3,5-triazine, 2,4,6-tris(3,5-di-tert-butyl-4-hydroxyphenoxy)-1,3,5-triazine, 1,3,5-tris(3,5-di-tert-butyl-4-hydroxybenzyl)isocyanurate, 1,3,5-tris(4-tert-butyl-3-hydroxy-2,6-dimethylbenzyl)isocyanurate, 2,4,6-tris(3,5-di-tert-butyl-4-hydroxyphenylethyl)-1,3,5-triazine, 1,3,5-tris(3,5-di-tert-butyl-4-hydroxyphenylpropionyl) hexahydro-1,3,5-triazine, 1,3,5-tris(3,5-dicyclohexyl-4-hydroxybenzyl)isocyanurate; benzylphosphonates, for example, 2,5-di-tert-butyl-4-hydroxybenzyldimethylphosphonate, 3,5-di-tert-butyl-4-hydroxybenzyldiethylphosphonate, 3,5-di-tert-butyl-4-hydroxybenzyldioctadecylphosphonate, 3,5-di-tert-butyl-4-hydroxy-3-methylbenzyldioctadecylphosphonate, calcium salt of 3,5-di-tert-butyl-4-hydroxybenzylmonoethylphosphonate; acylaminophenols, for example, lauric 4-hydroxyanilide, stearic 4-hydroxyanilide, octylN-(3,5-di-tert-butyl-4-hydroxyphenyl)-carbamate; esters of the following mono or polyvalent alcohols with β-(3,5-di-tert-butyl-4-hydroxyphenyl)propionate, examples of the alcohol include: methanol, ethanol, n-octanol, isooctanol, octadecanol, 1,6-hexanediol, 1,9-nonanediol, ethyleneglycol, 1,2-propanediol, neopentylglycol, thiodiethyleneglycol, diethyleneglycol, triethyleneglycol, pentaerythritol, tris(hydroxyethyl)isocyanurate, N,N′-bis(hydroxyethyl)succinic diamide, 3-thiaundecanol, 3-thiapentadecanol, trimethylhexanediol, trimethylol propane, 4-hydroxymethyl-1-phospha-2,6,7-trioxabicyclo[2,2,2]octane; an ester of the following mono or polyvalent alcohol with β-(5-tert-butyl-4-hydroxy-3-methylphenyl)propionate, examples of the alcohol include: methanol, ethanol, n-octanol, isooctanol, octadecanol, 1,6-hexanediol, 1,9-nonanediol, ethyleneglycol, 1,2-propanediol, neopentylglycol, thiodiethyleneglycol, diethyleneglycol, triethyleneglycol, pentaerythritol, tris(hydroxyethyl)isocyanurate, N,N′-bis(hydroxyethyl)succinic diamide, 3-thiaundecanol, 3-thiapentadecanol, trimethylhexanediol, trimethylol propane, 4-hydroxymethyl-1-phospha-2,6,7-trioxabicyclo[2,2,2]octane; esters of the following mono or polyvalent alcohols with β-(3,5-dicyclohexyl-4-hydroxyphenyl)propionate, examples of the alcohol include: methanol, ethanol, n-octanol, isooctanol, octadecanol, 1,6-hexanediol, 1,9-nonanediol, ethyleneglycol, 1,2-propanediol, neopentylglycol, thiodiethyleneglycol, diethyleneglycol, triethyleneglycol, pentaerythritol, tris(hydroxyethyl)isocyanurate, N,N′-bis(hydroxyethyl)succinic diamide, 3-thiaundecanol, 3-thiapentadecanol, trimethylhexanediol, trimethylol propane, 4-hydroxymethyl-1-phospha-2,6,7-trioxabicyclo[2,2,2]octane; an ester of the following mono or polyvalent alcohol with β-3,5-di-tert-butyl-4-hydroxyphenyl)acetate, examples of the alcohol include: methanol, ethanol, n-octanol, isooctanol, octadecanol, 1,6-hexanediol, 1,9-nonanediol, ethyleneglycol, 1,2-propanediol, neopentylglycol, thiodiethyleneglycol, diethyleneglycol, triethyleneglycol, pentaerythritol, tris(hydroxyethyl)isocyanurate, N,N′-bis(hydroxyethyl)succinic diamide, 3-thiaundecanol, 3-thiapentadecanol, trimethylhexanediol, trimethylol propane, 4-hydroxymethyl-1-phospha-2,6,7-trioxabicyclo[2,2,2]octane; β-(3,5-di-tert-butyl-4-hydroxyphenyl)propionic amide, for example, N,N′-bis(3,5-di-tert-butyl-4-hydroxyphenylpropionyl)hexamethylene diamine, N,N′-bis(3,5-di-tert-butyl-4-hydroxyphenylpropionyl)trimethylene diamine, N,N′-bis(3,5-di-tert-butyl-4-hydroxyphenylpropionyl)hydrazine; amine-based antioxidants, for example, N,N′-diisopropyl-p-phenylenediamine, N,N′-di-sec-butyl-p-phenylenediamine, N,N′-bis(1,4-dimethylpentyl)-p-phenylenediamine, N,N′-bis(1-ethyl-3-methylpentyl)-p-phenylenediamine, N,N′-bis(1-methylheptyl)-p-phenylenediamine, N,N′-dicyclohexyl-p-phenylenediamine, N,N′-diphenyl-p-phenylenediamine, N,N′-bis(naphtyl)-p-phenylenediamine, N-isopropyl-N′-phenyl-p-phenylenediamine, N-(1,3-dimethylbutyl-N′-phenyl-p-phenylenediamine, N-(1-methylheptyl)-N′-phenyl-p-phenylenediamine, N-cyclohexyl-N′-phenyl-p-phenylenediamine, 4-(p-toluenesulphamoyl)diphenylamine, N,N′-dimethyl-N,N′-di-sec-butyl-p-phenylenediamine, diphenylamine, N-allyldiphenylamine, 4-isopropoxydiphenylamine, N-phenyl-1-naphtylamine, N-(4-tert-octylphenyl)-1-naphtylamine, N-phenyl-2-naphtylamine, octylated diphenylamine, for example, p,p′-di-tertiary-butyloctyl diphenylamine, 4-n-butylaminophenol, 4-butylylaminophenol, 4-nonanoyl aminophenol, 4-dodecanoylaminophenol, 4-octadodecanoylaminophenol, bis(4-methoxyphenyl)amine, 2,6-d-tertiarybutyl-4-dimethylaminomethylphenol, 2,4′-diaminodiphenylmethane, 4,4′-diaminodiphenylmethane, N,N,N′,N′-tetramethyl-4,4′-diaminodiphenylmethane, 1,2-bis[(2-methylphenyl)aminoethane, 1,2-bis(phenylamino)propane, (o-tolyl)biguanide, bis[4-(1′,3′-dimethylbutyl)phenyl]amine, tertiary-octylated N-phenyl-1-naphtylamine, a mixture of a mono- and dialkylated tert-butyl/tert-octyldiphenylamine, a mixture of a mono- and dialkylated tert-butyl/tert-nonyldiphenylamine, a mixture of a mono- and dialkylated tert-butyl/tert-dodecyldiphenylamine, a mixture of a mono- and dialkylated isopropyl/isohexcyldiphenylamine, a mixture of a mono- and dialkylated tert-butyldiphenylamine, 2,3-dihydro-3,3-dimethyl-4H-1,4-benzothiadine, phenothiadine, a mixture of a mono- and dialkylated tert-butyl/tert-octylphenothiadine, a mixture of a mono- and dialkylated tert-butyloctylphenothiadine, N-allylphenothiadine, N,N,N′,N′-tetrapheyl-1,4-diaminobuto-2-en, N,N-bis(2,2,6,6-tetramethyl-pyperido-4-yl)hexamethylenediamine, bis(2,2,6,6-tetramethylpyperido-4-yl)sebacate, 2,2,6,6-tetramethyl-pyperidine-4-ol; 2-(2′-hydroxyphenyl)benzotriazole, for example, 2-(2′-hydroxy-5′-methylphenyl)benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyl)-5-chloro-benzotriazole, 2-(3′-tert-butyl-2′-hydroxy-5′-methyl-phenyl)-5-chloro-benzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′-hydroxyphenyl)benzotriazole, 2-(3′,5′-bis(.alpha.,.alpha.-dimethylbenzyl)-2′-hydroxyphenyl)benzotriazo-le, 2-(3′-tert-butyl-2′-hydroxy-5′-(2-octylcarbonylethyl)phenyl)-5-chloro-benzotriazole, and a mixture thereof, 2-(3′-tert-butyl-5′-[2-(2-ethylhexyloxy)carbonylethyl]-2′-hydroxyphenyl)-5-chloro-benzotriazole, 2-(3′-tert-butyl-2′-hydroxy-5′-(2-methoxycarbonylethyl)phenyl)-5-chloro-b-enzotriazole, 2-(3′-tert-butyl-2′-hydroxy-5′-(2-methoxycarbonylethyl)phenyl)benzotriazole, 2-(3′-tert-butyl-2′-hydroxy-5′-(2-octyloxycarbonylethyl)phenyl)benzotriazole, 2-(3′-tert-butyl-2′-hydroxy-5′-[2-(2-ethylhexyloxy)-carbonylethyl]-2′-hydroxyphenyl)benzotriazole, 2-(3′-dodecyl-2′-hydroxy-5′-methylphenyl)benzotriazole, and 2-(3′-tert-butyl-2′-hydroxy-5′-(2-isooctyloxycarbonylethyl)phenyl)benzotriazole, and 2,2′-methylene-bis[4-(1,1,3,3-tetramethylbutyl)-6-benzotriazole-2-yl-phen-ol]; an esterification product of 2-[3′-tert-butyl-5′-(2-methoxycarbonylethyl)-2′-hydroxyphenyl]-2H-benzotr-iazole with polyethyleneglycol 300; [R—CH₂CH₂—COO(CH₂)₃]₂ (in the formula, R=3′-tert-butyl-4′-hydroxy-5′-2H-benzotriazole-2-yl-phenyl); 2-hydroxybenzophenone, for example, 4-hydroxy-, 4-methoxy-, 4-octyloxy-, 4-decyloxy-, 4-dodecyloxy-, 4-benzyloxy-, 4,2,4-trihydroxy-, and 2′-hydroxy-4,4′-dimethoxy-derivatives; a substituted and nonsubstituted ester of benzoic acid, for example, 4-tert-butylphenyl salicylate, phenyl salicylate, octylphenyl salicylate, dibenzoyl resorcinol, bis(4-tert-butylbenzoyl) resorcinol, benzoyl resorcinol, 3,5-di-tert-butyl-4-hydroxy benzoicacid 2,4-di-tert-butylphenyl, 3,5-di-tert-butyl-4-hydroxy benzoic acid hexadecyl, 3,5-di-tert-butyl-4-hydroxy benzoic acid 2-methyl-4,6-di-tert-butylphenyl; a hindered amine-, for example, bis(2,2,6,6-tetramethyl-4-pyperidyl)sebacate, bis(2,2,6,6-tetramethyl-4-pyperidyl)succinate, bis(1,2,2,6,6-pentamethyl-4-pyperidyl)sebacate, n-butyl-3,5-di-tert-butyl-4-hydroxybenzyl maloatebis(1,2,2,6,6-pentamethyl-4-pyperidyl), a condensation product of 1-(2-hydroxyethyl)-2,2,6,6-tetramethyl-4-hydroxypyperidine with succinic acid, a condensation product of 1-N,N′-bis(2,2,6,6-tetramethyl-4-pyperidyl)hexamethylenediamine with 4-tert-octyl-amino-2,6-dichloro-1,3,5-triazine, nitrylotriacetictris(2,2,6,6-tetramethyl-4-pyperidyl), 1,2,3,4-butanetetracarboxylic acid tetrakis(2,2,6,6-tetramethyl-4-pyperidyl), 1,1′-(1,2-ethanedyl)-bis(3,3,5,5-tetramethylpyperadinone)4-benzoyl-2,2,6,-6-tetramethylpyperidine, 4-stearyloxy-2,2,6,6-tetramethylpyperidine, 2-n-butyl-2-(2-hydroxy-3,5-di-tert-butylbenzyl)malonic acid bis(1,2,2,6,6-pentamethylpyperidyl), 3-n-octyl-7,7,9,9-tetramethyl-1,3,8-triazaspyro[4,5]decane-2,4-dion, bis(1-octyoxy-2,2,6,6-tetramethylpyperidyl)sebacate, bis(1-octyoxy-2,2,6,6-tetramethylpyperidyl)succinate, a condensation product of N,N′-bis(2,2,6,6-tetramethyl-4-pyperidyl) hexamethylenediamine with 4-morpholino-2,6-dichloro-1,3,5-triazine, a condensation product of 2-chloro-4,6-bis(4-n-butylamino-2,2,6,6-tetramethyl-4-pyperidyl)-1,3,5-triazine with 1,2-bis(3-aminopropylamino)ethane, a condensation product of 2-chloro-4,6-bis(4-n-butylamino-1,2,2,6,6-pentmethyl-4-pyperidyl)-1,3,5-triazine with 1,2-bis(3-aminopropylamino) ethane, 8-acetyl-3-dodecyl-7,7,9,9-tetramethyl-1,3,8-triazaspyro[4,5]decane-2,4-d-ion, 3-dodecyl-1-(2,2,6,6-tetramethyl-4-pyperidyl)pyrodine-2,5-dion, 3-dodecyl-1-(1,2,2,6,6-pentamethyl-4-pyperidyl)pyrodine-2,5-dion, a mixture of 4-hexadecyloxy- and 4-stearyloxy-2,2,6,6-tetramethylpyperidines, a condensation product of N,N′-bis(2,2,6,6-tetramethyl-4-pyperidyl) hexamethylenediamine with 4-cyclohexylamino-2,6-di-chloro-1,3,5-triazine, a condensation product of 1,2-bis(3-aminopropylamino)ethane with 2,4,6-trichloro-1,3,5-triazine, and 4-butylamino-2,2,6,6-tetramethyl-4-pyperidine (CAS Reg. No. [136504-96-6]); N-(2,2,6,6-tetramethyl-4-pyperidyl)-n-dodecyl succinimide, N-(1,2,2,6,6-pentmethyl-4-pyperidyl)-n-dodecyl succinimide, 2-undecyl-7,7,9,9-tetramethyl-1-oxa-3,8-diaza-4-oxo-spyro[4,5]decane, a reaction product of 7,7,9,9-tetramethyl-2-cycloundecyl-1-oxa-3,8-diaza-4-oxo-spyro[4,5]decane with epichlorohydrin; 2-(2-hydroxyphenyl)-1,3,5-triazine, for example, 2,4,6-tris(2-hydroxy-4-octyloxyphenyl)-1,3,5-triazine, 2-(2-hydroxy-4-octyloxyphenyl)-4,6-bis(2,4-dimethylphenyl)-1,3,5-triazine, 2-(2,4-dihydroxyphenyl)-4,6-bis(2,4-dimethylphenyl)-1,3,5-triazine, 2,4-bis(2-hydroxy-4-propyloxyphenyl)-6-(2,4-dimethylphenyl)-1,3,5-triazine, 2-(2-hydroxy-4-octyloxyphenyl)-4,6-bis(4-methylphenyl)-1,3,5-triazine, 2-(2-hydroxy-4-dodecyloxyphenyl)-4,6-bis(2,4-dimethylphenyl)-1,3,5-triazi-ne, 2-(2-hydroxy-4-tridecyloxyphenyl)-4,6-bis(2,4-dimethylphenyl)-1,3,5-tr-iazine, 2-[2-hydroxy-4-(2-hydroxy-3-butyloxy-propyloxy)phenyl]-4,6-bis(2,4-dimethylphenyl)-1,3,5-triazine, 2[2-hydroxy-4-(2-hydroxy-4-(2-hydroxy-3-octloxy-propyloxy)phenyl]-4,6-bis(−2,4-dimethylphenyl)-1,3,5-triazine, 2-[4-(dodecyloxy/tridecyloxy-2-hydroxypropoxy)-2-hydroxyphenyl]-4,6-bis(2-,4-dimethylphenyl)-1,3,5-triazine, 2-[2-hydroxy-4-(2-hydroxy-3-dodecyloxypropoxy)phenyl]-4,6-bis(2,4-dimethylphenyl)-1,3,5-triazine,2-(2-hydroxy-4-hexyloxy)phenyl-4,6-diphenyl)-1,3,5-triazine, 2-(2-hydroxy-4-methoxyphenyl)-4,6-diphenyl-1,3,5-triazine, 2,4,6-tris[2-hydroxy-4-(3-butoxy-2-hydroxy-propoxy)phenyl]-1,3,5-triazine-, 2-(2-hydroxyphenyl)-4-(4-methoxyphenyl)-6-phenyl-1,3,5-triazine; a phosphite or a phosphonite, for example, triphenyl phosphonite, diphenyl phosphonite alkyl, phenylphosphonite dialkyl, trisnonylphenyl phosphonite, lauryl phosphonite, trioctadecyl phosphonite, distearyl pentaerythritol diphosphite, tris(2,4-di-tert-butyl-phenyl) phosphonite, diisodecyl pentaerythritol diphosphite, bis(2,4-di-tert-butyl-4-methylphenyl) pentaerythritol diphosphite, bis(2,6-di-tert-butyl-4-methylphenyl) pentaerythritoldiphosphite, bis-isodecyl pentaerythritol diphosphite, bis(2,4-di-tert-butyl-6-ethylphenyl) pentaerythritol diphosphite, bis(2,4,6-tri-tert-butyl-6-methylphenyl) pentaerythritol diphosphite, tetrakis(2,4-di-tert-butylphenyl)4,4′-biphenylenephosphite, 6-isooctyloxy-2,4,8,10-tetra-tert-butyl-12H-dibenz[d,g]-1,3,2-dioxaphosphocine, 6-fluoro-2,4,8,10-tetra-tert-butyl-[2-methyl-dibenz[d,g]-1,3,2-dioxaphosphocine, bis(2,4-di-tert-butyl-6-methylphenyl)methyl phosphite, and bis(2,4-di-tert-butyl-6-methylphenyl)ethyl phosphite. Of these, tris(2,4-di-tert-butylphenyl)phosphite is preferred.

Optical brighteners include bisbenzoxazoles, bis-(styryl)biphenyls, phenylcoumarins (in particular, triazine-phenylcoumarins, benzotriazole-phenylcoumarins and naphthotriazole-phenylcoumarins) and triazine-stilbenes. A broad range of optical brighteners is commercially available, such as Tinopal® (Ciba-Geigy, Basle, Switzerland), Hostalux® KS (Clariant, Germany), or Eastobrite® OB-1 (Eastman). In preferred embodiments of the present invention, the composition contains at least one optical brightener.

In preferred embodiments the composition does not contain any hindered amine light stabilizer, does not contain any thermal stabilizer, or does not contain any of a hindered amine light stabilizer and a thermal stabilizer.

In other embodiments the PLED device includes one or more components that are made from compositions that contain the aromatic PE and/or the wholly aromatic PE (usually LCPs) and one or more other materials. Preferably, any component of the PLED device that is at least partially made from the aromatic PE and/or the wholly aromatic PE (usually LCPs) contains at least 30% by weight of the aromatic LCP or the wholly aromatic LCP based on the total weight of the component. In other embodiments a part that is partially made from the aromatic PE and/or the wholly aromatic PE (usually LCPs) may contain at least 40%, at least 50%, at least 60%, at least 70%, at least 80%, at least 90%, at least 95%, at least 96%, at least 97%, at least 98%, at least 99%, or at least 99.5% by weight of said PEs based on the total weight of the part that is at least partially made from said PEs. In other embodiments one or more components of the Power LED device consist essentially of the aromatic PE and/or the wholly aromatic PE (usually LCPs).

The aromatic PE and/or the wholly aromatic PE (usually LCPs) composition used to make any component of the PLED device, preferably the reflector, may contain one or more filler materials. The fillers can be in the form of nano-scale or micro-scale powders, fibers, filaments, flakes, platelets, whiskers, wires, tubes, or particulates for homogenous dispersion. Suitable fillers may be solid or hollow, and include, for example, metal (or metal alloy) powder, metal oxide and salts, ceramics, particulates, carbonaceous materials, polymeric materials, glass microspheres, and the like or blends thereof. Non-limiting examples of metal (or metal alloy) powders include bismuth, brass, bronze, cobalt, copper, inconel, iron, molybdenum, nickel, stainless steel, titanium, aluminum, tungsten, beryllium, zinc, magnesium, manganese, and tin. Fillers are preferably electrically insulative inorganic materials such as metal oxides and salts. Non-limiting examples of metal oxides and salts include zinc oxide, iron oxide, aluminum oxide, titanium dioxide, magnesium oxide, zirconium oxide, tungsten trioxide, zirconium oxide, tungsten carbide, tungsten oxide, tin oxide, zinc sulfide, zinc sulfate, zinc carbonate, barium sulfate, barium carbonate, calcium carbonate, calcium metasilicate, magnesium carbonate, and silicates. Non-limiting examples of carbonaceous materials include graphite and carbon black. Examples of other useful fillers include precipitated hydrated silica, boron, clay, talc, glass fibers, aramid fibers, mica, and diatomaceous earth.

Preferably the filler is one or more of wollastonite, talc, titanium dioxide, zinc oxide, a crystalline silicate selected from the group consisting of nesosilicates, sorosilicates, cyclosilicates, tectosilicates, and inosilicates.

The filler is preferably present in an amount of 5% by weight or more based on the total weight of the PE composition. In other embodiments the filler is present in amounts of from 1 to 5 wt %, preferably 2 to 5 wt %, 3 to 5 wt %, or 4 to 5 wt %. In other embodiments one or more filler are present in a total amount of up to 50 wt % of the PE composition, preferably up to 40 wt %, 35 wt %, 30 wt %, 25 wt %, 20 wt %, 15 wt %, or 10 wt %.

In an especially preferred embodiment the filler is a white filler such as titanium dioxide or talc.

The PE composition contains usually a polyester (usually a LCP) that is a polycondensation product of at least one aromatic dicarboxylic acid monomer compound and at least one aromatic diol monomer compound. In a preferable embodiment the aromatic PE and/or the wholly aromatic PE (usually LCPs) contain polycondensed units of at least one hydroxycarboxylic acid monomer compound, at least one aromatic dicarboxylic acid monomer compound and at least one aromatic diol monomer compound.

In some embodiments of the invention one or more components of the Power LED device is made from an aromatic polyester that may be a liquid crystalline polyester. As used herein an aromatic polyester contains at least 80 mol % of aromatic monomer units. The aromatic polyester may contain polycondensed units of aromatic monomers such as the structural units described below for the wholly aromatic polyester. Preferably the aromatic polyester contains at least 80 mol %, at least 85 mol %, at least 90 mol %, at least 95 mol %, at least 97 mol %, at least 99 mol % or at least 99.5 mol % of polycondensed aromatic monomer units. In the context of the invention the terms “monomer units” and “structural units” refer to the chemical units present in the chemical structure of the polyesters in their respective polycondensed forms. The aromatic polyester is not wholly aromatic. For example, the aromatic polyester may further include non aromatic structural units, such as polycondensed units of adipic acid, sebacic acid, ethylene glycol and butylene glycol monomers, provided the amount of such non aromatic structural units does not exceed 20 mol %. The aromatic polyester may also include aromatic structural units interrupting the wholly aromatic characteristics of the aromatic polyester, as above explained; for example, the aromatic polyester may further include aromatic group-containing structural units that contain more than one aromatic group connected by an aliphatic group, in particular polymerized units of the diol monomer compound bis-phenol A.

The aromatic PE and the wholly aromatic PE (usually LCPs) may contain, independently from each other, polycondensed units of one or more of the following aromatic dicarboxylic acid monomer units: terephthalic acid, isophthalic acid, 2,6-naphthalic dicarboxylic acid, 3,6-naphthalic dicarboxylic acid, 1,5-naphthalic dicarboxylic acid, 2,5-naphthalic dicarboxylic acid, 2,7-naphthalic dicarboxylic acid, 1,4-naphthalic dicarboxylic acid, 4,4′-dicarboxybiphenyl, and alkyl, aryl, alkoxy, aryloxy or halogen substituted derivatives thereof.

In addition to polycondensed units of aromatic dicarboxylic acid monomer compounds, the aromatic PE and the wholly aromatic PE (usually LCPs) may also contain, independently from each other, polycondensed units of one or more of the following diol monomer units: 4,4′-biphenol, hydroquinone, resorcinol, 3,3′-biphenol, 2,4′-biphenol, 2,3′-biphenol, and 3,4′-biphenol, 2,6 dihydroxynaphthalene, 2,7-dihydroxynaphthalene, 1,6 dihydroxynaphthalene, 1,4-dihydroxynaphthalene, and alkyl, aryl, alkoxy, aryloxy or halogen substituted derivatives thereof.

Optionally, the aromatic PE and the wholly aromatic PE (usually LCPs) may contain, independently from each other, polycondensed units of one or more of the following aromatic hydroxycarboxylic acid monomer units: p-hydroxybenzoic acid, 5-hydroxyisophthalic acid, m-hydroxybenzoic acid, o-hydroxybenzoic acid, 4′hydroxyphenyl-4-benzoic acid, 3′-hydroxyphenyl-4-benzoic acid, 4′hydroxyphenyl-3-benzoic acid, 2,6-hydroxynaphthalic acid, 3,6-hydroxynaphthalic acid, 3,2-hydroxynaphthalic acid, 1,6-hydroxynaphthalic acid, and 2,5-hydroxynaphthalic acid, and alkyl, aryl, alkoxy, aryloxy or halogen substituted derivatives thereof.

The aromatic PE and the wholly aromatic PE (usually LCPs) can optionally include, independently from each other, one or more of the following structural units:

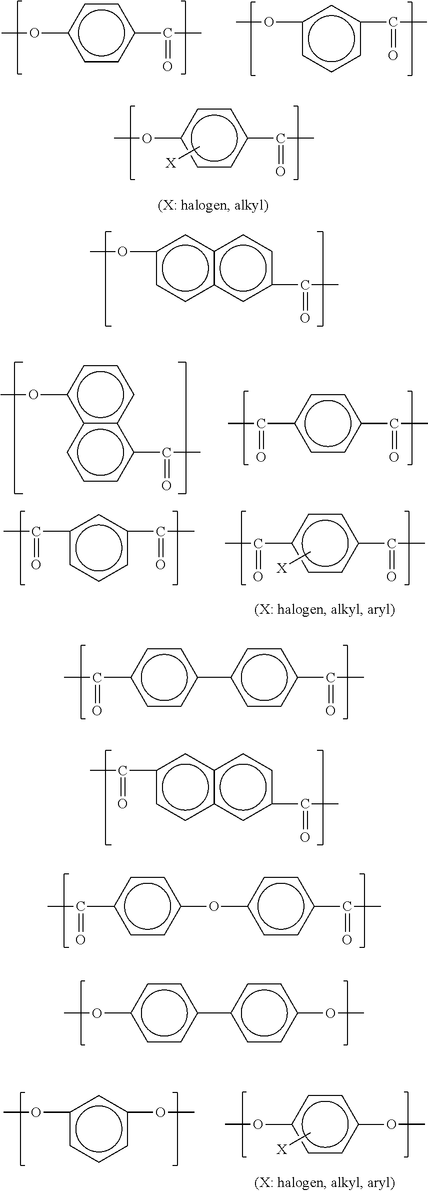

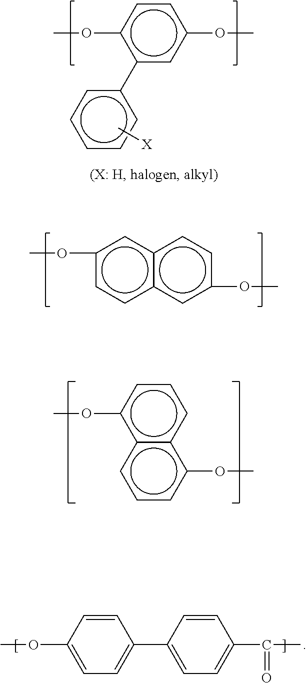

In a preferable embodiment of the invention the aromatic PE and the wholly aromatic PE (usually LCPs) of the invention comprise at least one of the following structural units:
structural units (I) derived from hydroquinone,

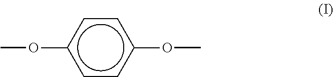

structural units (II) derived from 4,4′-biphenol,

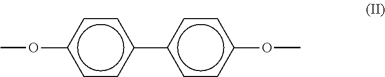

structural units (III) derived from terephthalic acid,

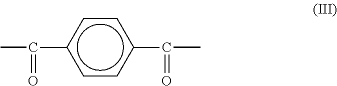

structural units (V) derived from p-hydroxybenzoic acid,

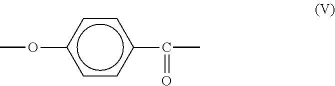

and, optionally in addition, structural units (IV) derived from isophthalic acid;

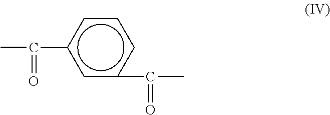

In other embodiments of the invention, the aromatic polyester and wholly aromatic polyester (usually LCPs) contain only one of the structural units (I), (II), (III) and (V), preferably at least two of the structural units (I)-(V), more preferably at least three of the structural units (I)-(V), even more preferably at least four of the structural units (I)-(V). In still other embodiments of the invention the aromatic PE and the wholly aromatic PE (usually LCPs) contain only two of the structural units (I)-(V), more preferably only three of the structural units (I)-(V), even more preferably only four of the structural units (I)-(V).

The aromatic PE and the wholly aromatic PE (usually LCPs) may also comprise, independently from each other, polymerized monomer units corresponding to structural units (I), (II), (III), (IV) and (V) in the following amounts: 5-40 mole % of a mixture of hydroquinone (I) and 4,4′-biphenol (II); 5-40 mole % of a mixture that comprises terephthalic acid (III) and isophthalic acid (IV); and 40-90 mole % of p-hydroxybenzoic acid (V). Mole % is based on the total number of moles of polymerized monomer units corresponding to structural units (I)-(V) present in the PEs.

Preferably the aromatic PE and the wholly aromatic PE (usually LCPs) comprise polymerized monomer units corresponding to structural units (I), (II), (III), (IV) and (V) in the following amounts: 10-30 mole % of a mixture of hydroquinone (I) and 4,4′-biphenol (II); 10-30 mole % of a mixture that comprises terephthalic acid (III) and isophthalic acid (IV); and 40-80 mole % of p-hydroxybenzoic acid (V). Mole % is based on the total number of moles of polymerized monomer units corresponding to structural units (I)-(V) present in the PEs.

In another embodiment the aromatic PE and the wholly aromatic PE (usually LCPs) comprise polymerized monomer units corresponding to structural units (I), (II), (III), (IV) and (V) in the following amounts: 13-28.5 mole %, preferably 15-25 mole %, more preferably 18-22 mole % of a mixture of hydroquinone (I) and 4,4′-biphenol (II); 13-28.5 mole %, preferably 15-25 mole %, more preferably 18-22 mole % of a mixture that comprises terephthalic acid (III) and isophthalic acid (IV); and 43-74 mole %, preferably 45-70 mole %, more preferably 50-60 mole % of p-hydroxybenzoic acid (V). Mole % is based on the total number of moles of polymerized monomer units corresponding to structural units (I)-(V) present in the PEs.

In the aromatic PE and the wholly aromatic PE (usually LCPs) the mole ratio of the number of moles of monomer units derived from isophthalic acid to the number of moles of monomer units derived from terephthalic acid may be from 0 to less than or equal 0.1. The aromatic PE and the wholly aromatic PE (usually LCPs) may optionally include structural units derived from isophthalic acid.

In the aromatic PE and the wholly aromatic PE (usually LCPs) the ratio of the number of moles of monomer units derived from hydroquinone to the number of moles of monomer units derived from 4,4′-biphenol may be from 0.1 to 1.50. Preferably the molar ratio of the number of moles of monomer units derived from hydroquinone to the number of moles of monomer units derived from 4,4′-biphenol is from 0.2 to 1.25, 0.4 to 1.00, 0.6 to 0.8, or 0.5 to 0.7.

The molar ratio of structural units derived from monomers hydroquinone and 4,4′-biphenol to units derived from terephthalic and isophthalic acid is preferably from 0.95 to 1.05.

The mole ratio of oxybenzoyl units to the sum of terephthalic and isophthalic units may be within the range of from about 1.33:1 to about 8:1, i.e., compositions containing 60 to 85 mol % of p-hydroxybenzoic acid with respect to sum of p-hydroxybenzoic acid and total diols and further defined by isophthalic acid content of 0% to 0.09 mol % with respect to sum of the mols of isophthalic and terephthalic acid.

The terms “structural units”, “polymerized monomer units”, and “monomer units derived from” refer to the chemical units present in the chemical structure of the aromatic PE and the wholly aromatic PE in their respective polycondensed forms. Formulas (I)-(V) above show the examples of the structures of these units. The term “monomer compound” refers to the pure aromatic diol, aromatic dicarboxylic acid or aromatic hydroxycarboxylic acid compound as it exists before undergoing an alcohol/acid polycondensation reaction.

The aromatic PE and the wholly aromatic PE (usually LCPs) may optionally include, independently from each other, one or more other polymerized aromatic monomer units derived from one or more compounds other than p-hydroxybenzoic acid, terephthalic acid, isophthalic acid, hydroquinone and 4,4′-biphenol.

In a preferable embodiment, the aromatic PE and the wholly aromatic PE (usually LCPs) include polymerized monomer units that contain one or more naphthyl groups. For example, they may include one or more of 3-hydroxy-2-naphthoic acid, 6-hydroxy-2-naphthoic acid, 2-hydroxynaphthalene-3,6-dicarboxylic acid, 2,6-naphthalic dicarboxylic acid, 3,6-naphthalic dicarboxylic acid, 1,5-naphthalic dicarboxylic acid, 2,5-naphthalic dicarboxylic acid, 2,7-naphthalic dicarboxylic acid, 1,4-naphthalic dicarboxylic acid, 2,6-dihydroxynaphthalene, 2,7-dihydroxynaphthalene, 1,6-dihydroxynaphthalene, 1,4-dihydroxynaphthalene, and alkyl, aryl, alkoxy, aryloxy or halogen substituted derivatives thereof.

Preferably, the wholly aromatic PE (usually an LCP) contains only monomer units derived from p-hydroxybenzoic acid, terephthalic acid, isophthalic acid, hydroquinone and 4,4′-biphenol, or only monomer units derived from p-hydroxybenzoic acid, terephthalic acid, hydroquinone and 4,4′-biphenol. Within the context of the invention, the wholly aromatic PE (usually an LCP) includes polycondensed reaction products made from a mixture of p-hydroxybenzoic acid, terephthalic acid, isophthalic acid, hydroquinone and 4,4′-biphenol, that further includes other aromatic and non-aromatic monomer compounds present as unavoidable or adventitious impurities in the aromatic monomer compounds.

In preferred embodiments the aromatic PE and the wholly aromatic PE (usually LCPs) comprise polymerized monomer units (i.e., polymerized structural units) in the following amounts: 50-70 mole % of p-hydroxybenzoic acid; 15 to 25 mole % of a mixture that comprises terephthalic acid and isophthalic acid; and 15-25 mole % of a mixture of hydroquinone and 4,4′-biphenol. All values and subranges between the stated values are expressly included herein as if written out, for example, p-hydroxybenzoic acid may be present in a range of 45-75, 55-65, and about 60 mole %, the mixture of terephthalic and isophthalic acid may be present in amounts of 12.5-27.5, 22.5-27.5, and about 20 mole %; and the mixture of hydroquinone and 4,4′-biphenol may be present in amounts of 12.5-27.5, 27.5-22.5, and about 20 mole %. All numbers between the stated values are expressly included herein as if written out, e.g., values between an exemplary range of 22.5 to 27.5 mole % include 23, 24, 25, 26, and 27 mole %. Mole % is based on the total number of moles of polymerized monomer units corresponding to structural units (I)-(V) present in the PEs.

In preferred embodiments the aromatic PE and the wholly aromatic PE (usually LCPs) comprise polymerized monomer units (i.e., polymerized structural units) in the amounts that satisfy the following formulas:

$$\begin{matrix}45 \% \leq \frac{V}{( I + II + III + IV + V )} \leq 75 \% & ( 1 ) \\ 0.1 \leq \frac{I}{II} \leq 1.50 & ( 2 ) \\ 0 \leq \frac{IV}{III} \leq 0.08 & ( 3 )\end{matrix}$$

where I, II, III, IV and V represent the molar amounts of the respective monomers described above.

In further preferred embodiments the aromatic PE and the wholly aromatic PE (usually LCPs) include polymerized structural units in the following amounts: 55-65 mole % of p-hydroxybenzoic acid; 16 to 23 mole % of terephthalic acid; 0 to 2 mole % of isophthalic acid; 1.5 to 14 mole % of hydroquinone; and 7 to 21 mole % of 4,4′-biphenol. More preferable still are embodiments in which the polymerized structural units are present in the following amounts: 58-62 mole % of p-hydroxybenzoic acid; 18 to 21 mole % of terephthalic acid; 0.1 to 1.0 mole % of isophthalic acid; 3.2 to 12.6 mole % of hydroquinone; and 7.5 to 17.5 mole % of 4,4′-biphenol. As stated above, all numbers and subranges between the stated values are expressly included as if written out. In the case of isophthalic acid decimal amounts of the monomer compound are expressly included, for example the range 0.1-5 mole % includes 0.1, 0.2, 0.3, 0.4, 0.5, 0.6, 0.7, 0.8, 0.9, and 1.0 mole % as well as any decimal amount between 1.0 and 5 mole %. Preferably the amount of isophthalic acid is 2 mole % or less.

In further preferred embodiments the aromatic PE and the wholly aromatic PE (usually LCPs) comprise polymerized monomer units (i.e., polymerized structural units) in the amounts that satisfy the following formulas:

$$\begin{matrix}45 \% \leq \frac{V}{( I + II + III + IV + V )} \leq 70 \% & ( 4 ) \\ 0.1 \leq \frac{I}{II} \leq 1.50 & ( 5 ) \\ 0 \leq \frac{IV}{III} \leq 0.056 & ( 6 )\end{matrix}$$

In a preferred embodiment the aromatic PE and the wholly aromatic PE (usually LCPs) include at least 95 mole %, preferably 96, 97, 98 or 99 mole % of structural units derived from p-hydroxybenzoic acid, terephthalic acid, isophthalic acid, hydroquinone and 4,4′-biphenol, with no more than 5, 4, 3, 2, 1 mole % of structural units derived from unavoidable or adventitious impurities present in the aromatic monomer compounds. In an especially preferred embodiment the wholly aromatic PE (usually an LCP) includes only structural units derived from p-hydroxybenzoic acid, terephthalic acid, isophthalic acid, hydroquinone and 4,4′-biphenol.

In other embodiments the aromatic PE and the wholly aromatic PE (usually LCPs) include at least 50 mole %, preferably 60, 70, 80, or 90 mole % of structural units derived from p-hydroxybenzoic acid, terephthalic acid, isophthalic acid, hydroquinone and 4,4′-biphenol, with the balance of structural units representing other aromatic monomer compounds.

In the aromatic PE and in the wholly aromatic PE (usually LCPs), the mole ratio of the number of moles of monomer units derived from isophthalic acid to the number of moles of monomer units derived from terephthalic acid may be preferably from 0.01 to less than 0.1, more preferably 0.02-0.5, 0.03-0.4. As stated above, fractions and decimal amounts are expressly included as if written out, e.g., the range 0.01-0.5 includes 0.01, 0.02, 0.03, 0.04, 0.05, 0.06, 0.07, 0.08, 0.09, 0.10, 0.2, 0.3, and 0.4 and any fraction, decimal value and subrange between the stated values.

In the aromatic PE and in the wholly aromatic PE (usually LCPs), the mole ratio of the number of moles of monomer units derived from hydroquinone to the number of moles of monomer units derived from 4,4′-biphenol is preferably 0.2-1.20, more preferably 0.3-1.1, 0.4-1.0, 0.5-0.9, 0.6-0.8, 0.65-0.75. As stated above, fractions and decimal amounts are expressly included as if written out, e.g., the range 0.2-0.1.15 includes 0.21-1.14, 0.23-1.07, 0.37-0.85, and any fraction, decimal value and subrange between the stated values.

The melting points (Tₘ) of the aromatic PE and of the wholly aromatic PE (usually LCPs) of the invention are preferably less than 400° C. and greater than 300° C., more preferably less than 390° C. and greater than 325° C., especially preferably about 375° C. The word “about” is used to mean that the temperature may vary by ±20° C. around the stated temperature. Therefore, a temperature of “about” 375° C. includes temperatures of 365, 366, 367, 368, 369, 370, 371, 372, 373, 374, 375, 376, 377, 378, 379, 380, 381, 382, 383, 384, and 385° C. In a preferred embodiment the aromatic PE and the wholly aromatic PE (usually LCPs) of the invention have a melting point of 370-380° C. or 360-385° C.

The aromatic PE and the wholly aromatic PE (usually LCPs) of the invention preferably have a heat distortion temperature of at least 280° C., preferably at least 290° C., most preferably at least 300° C. and higher according to either ASTM D648, at stress level 264 PSI or ISO 75, at stress level 1.82 MPa. A higher heat distortion temperature is indicative of a resin that tends to exhibit stiffness and less sag at high temperatures.

Properties of ductility, which are advantageous for molded part applications and processing, can be evaluated with diverse test procedures known to those skilled in the art. For example, tensile elongation stress and strain at break and flex stress and strain at break are useful measures of ductility for aromatic and wholly aromatic polyester resins and compounds. The aromatic polyester and the wholly aromatic polyester resins of the invention (usually LCPs) preferably have a flex strain at break of at least 1.0% and a flex stress at break of at least 10,000 psi according to ASTM D790 at strain rate of 0.05″/min or according to ISO 178 at strain rate 2 mm/min.

The aromatic polyester and wholly aromatic PEs (usually LCPs) of the invention preferably have a melt viscosity at 380° C. of from 500 to 2500 poise at shear rate 100 seq⁻¹ according to capillary rheology measurements known to those skilled in the art, that is, a molecular weight sufficient for fiber forming.

The Power LED devices of the invention may be used as a component of other devices. While the Power LED devices preferably emit light, the emission of other radiation is also possible. The Power LED devices may be used in applications such as keyless entry systems of an automobile, lighting in a refrigerator, liquid crystal display apparatuses, automobile front panel lighting apparatuses, desk lamps, headlights, household electrical appliance indicators and outdoor display apparatuses such as traffic signs, optoelectronic devices comprising at least one semi-conductor chip, mobile appliance applications such as, for example, cell phones and PDAs, flashlights, automotive day light running lights, signs and TVs. Preferably the device is a Power LED device such as a lighting source for interior or exterior lighting applications.

Another aspect of the present invention is related to the use of a Power LED device according to the present invention, for example as a lighting source for interior or exterior lighting applications. It is in particular directed to the use of a Power LED device that may feature some and preferably all the above described characteristics for the Power LED according to the present invention, for example as a lighting source for interior or exterior lighting applications. In a preferred embodiment, the present invention is directed to the use of a Power LED device comprising at least one part comprising the above described aromatic polyester or wholly aromatic polyester, for example as a lighting source for interior or exterior lighting applications.

Obviously, numerous modifications and variations of the present invention are possible in light of the above teachings. It is therefore to be understood that within the scope of the appended claims, the invention may be practiced otherwise than as specifically described herein.

### EXAMPLES

### Experimental Procedures

Color of resin powders packed in a 4×5×1 cm cuvette was measured according to ASTM E 308-06 using a Milton Roy Diano Color Products Scan II with D6500 illumination, CIELAB color scale, observation angle 2° (CIE 1931 standard observer), wavelength range 380 to 700 nm, 10-nm measurement interval. Polymer was ground and sieved by a 20 mesh screen to give a maximum particle size of 850 microns. The color difference for the resin powder compared to white reference tile was calculated using the CIELAB ΔE* (Delta E) equation. The white reference tile (S/N 4DD1202002) values for L*, a* and b* values were 100.01±0.03, −0.04±0.08 and 0.03±0.06, respectively.

Flexural strain at break and stress at break were measured according to method ASTM D790 at 0.05″/MIN, 2″ span and 23° C.

Heat deflection temperature, HDT, is reported in ° C. and was measured according to ASTM D648, at stress level 264 PSI, sample dimensions 5.0″ by 0.5″ by 0.25″; conditioning according to ASTM D-5183.

Thermal transitions, Tₘ and T_{c}, were measured using TA Instruments Differential Scanning Calorimeter Model Q20 or Q1000, or similar instrument. Each sample was evaluated by a first heating ramp followed by an isothermal heating for one minute, a cooling ramp and a second heating ramp. The sample was heated at 20° C./min from room temperature to either 400° C. or 420° C. and held for one minute; then the sample was cooled at 20° C./min to 30° C. and re-heated at 20° C./min to 400° C. or 420° C. Peak crystallization temperature, T_{c}, is determined from the cooling cycle. Peak melting temperature, Tₘ (also designated Tₘ₂), is determined from the second heating ramp.

Viscosity was measured at 380° C. using a Kayeness Galaxy V Rheometer (Model 8052 DM) with LC 9 kN, 2000 lb, melt time 250 sec. Polymer is ground and sieved by a 20 mesh screen to give a maximum particle size of 850 microns. Samples were dried at 150° C. for 15 min prior to testing.

ASTM flex bars were molded from unfilled resin samples using an 11-Ton Mini-Jector Wasp Model 55. Barrel temperatures ranged from 355° C. to 385° C. and mold temperatures ranged from 175° C. to 190° C.

### Examples 1 Through 8

### Synthesis of Polyesters Suitable for Use in the Manufacture of a Reflector of a Power LED Device

TABLE 1
Designations for Monomers and Structural Units

| Monomer | Designation | Structural Unit |
|---|---|---|
| p-hydroxybenzoic acid | A | V |
| terephthalic acid | B | III |
| isophthalic acid | C | IV |
| hydroquinone | D | I |
| 4,4′-biphenol | E | II |

In addition to the monomers, acylating reagents and catalysts known to those skilled in the art were employed in the synthesis of the resins of the invention.

### Example 1

The monomers in the amounts 505.9 g A, 270.6 g B, 5.8 g C, 85.4 g, D and 165.3 g E and catalyst were charged into a 2-liter reactor vessel equipped with an electrical heating mantle, overhead mechanical stirrer, reflux condenser, stopcock adapter and distillate receiver. The reactor was purged with nitrogen and then acetic anhydride was added. The mixture was constantly stirred and heated to a temperature of 145° C. and held under reflux for an additional hour. The distillation of acetic acid from the reaction was begun while the external temperature was increased at the rate of 0.5° C./min to 280° C. Then the heating rate was stepped to 0.75° C./min to 310° C. to form a pre-polymer. When the reaction reached 310° C. the heating mantle was turned off and removed for faster cooling. After the reactor cooled to ambient temperature, the pre-polymer was removed and ground to a particle size of about 1-2 mm. Solid state polymerization was carried out on the pre-polymer product by raising the temperature from room temperature to 310° C. over 12 hours and then maintaining temperature at 310° C. under continuous nitrogen flow for 3.75 hrs.

Differential scanning calorimetery (DSC) measurements for this polyester example indicated a temperature of crystallization, T_{c} of 329° C. and a melt temperature, Tₘ of 370° C. The viscosity at 380° C. with a shear rate of 100 seq⁻¹ was 890 poise.

### Example 2

This example followed the same procedure as Example 1. The ingredient amounts for Example 2 were the following: p-hydroxybenzoic acid (pHBA) 642.1 g, terephthalic acid (TA) 197.2 g, isophthalic acid (IA) 10.9 g, hydroquinone (HQ) 68.5 g, 4,4′-biphenol (BP) 117.2 g. The solid state polymerization was carried out for 13 minutes at 310° C. The DSC analysis gave temperature of crystallization of T_{c}=338° C. and the melt temperature Tₘ=382° C. The melt viscosity at 380° C. and shear rate of 100 seq⁻¹ was 1551 poise.

### Example 3

This example followed the same procedure as Example 1. The ingredient amounts for Example 3 were the following: p-hydroxybenzoic acid (pHBA) 568.3 g, terephthalic acid (TA) 227.8 g, hydroquinone (HQ) 30.2 g, 4,4′-biphenol (BP) 204.3 g.

The solid state advancing was carried out for 4.5 hrs at 310° C. The DSC analysis gave temperature of crystallization of T_{c}=335° C. and the melt temperature of Tₘ=372° C. The melt viscosity at 380° C. with shear rate of 100 seq⁻¹ was 690 poise.

### Example 4

This example followed the same procedure as Example 1. The ingredient amounts for Example 4 were the following: p-hydroxybenzoic acid (pHBA) 568.3 g, terephthalic acid (TA) 218.7 g, isophthalic acid (IA) 9.1 g, hydroquinone (HQ) 30.2 g, 4,4′-biphenol (BP) 204.3 g.

The solid state advancing was carried out for 4.5 hrs at 310° C. The DSC analysis gave temperature of crystallization of Tc=330° C. and Tm=368° C. The melt viscosity at 380° C. with shear rate of 100 seq⁻¹ was 600 poise.

### Example 5

This example followed the same procedure as Example 1. The ingredient amounts for Example 5 were the following: p-hydroxybenzoic acid (pHBA) 535.1 g, terephthalic acid (TA) 256.2 g, isophthalic acid (IA) 7.1 g, hydroquinone (HQ) 86.1 g, 4,4′-biphenol (BP) 149.5 g.

The solid state advancing was carried out for 2.75 hrs at 310° C. The DSC analysis gave temperature of crystallization of T_{c}=333° C. and Tₘ=367° C. The melt viscosity at 380° C. with shear rate of 100 seq⁻¹ was 1200 poise.

### Example 6

This example followed the same procedure as Example 1. The relative ingredient amounts for Example 6 were the following: p-hydroxybenzoic acid (pHBA) 60 mole %, terephthalic acid (TA) 19.2 mole %, isophthalic acid (IA) 0.8 mole %, hydroquinone (HQ) 7.5 mole %, 4,4′-biphenol (BP) 12.5 mole %.

The solid state advancing was carried out for a total of 14.5 hours with a stepwise heating profile under a nitrogen blanket, starting from 24° C. and ending with the last three hours at 310° C. The DSC analysis gave temperature of crystallization of T_{c}=337° C. and Tₘ=367° C. The melt viscosity at 380° C. with shear rate of 100 seq⁻¹ was 1100 poise.

### Example 7

After the temperature reached 280° C., heating was carried out at a rate of 2.0° C./min. Also lower excess of acetic anhydride was used when compared to Example 1. The ingredient amounts for Example 7 were the following: p-hydroxybenzoic acid (pHBA) 541.2 g, terephthalic acid (TA) 248.6 g, isophthalic acid (IA) 17.8 g, hydroquinone (HQ) 117.7 g, 4,4′-biphenol (BP) 112.8 g.

The solid state advancing was carried out for 23 minutes at 310° C. The DSC analysis gave temperature of crystallization of T_{c}=338° C. and Tₘ=387° C. The melt viscosity at 380° C. and the shear rate of 100 seq⁻¹ was 1900 poise.

### Example 8

Example 8 followed the same procedure as Example 7 but a temperature rate of 0.5° C./min was maintained until the end of the synthesis. Also the excess of acetic anhydride doubled and the amounts of catalysts were reduced. The ingredient amounts for Example 8 were the following: p-hydroxybenzoic acid (pHBA) 555.5 g, terephthalic acid (TA) 167 g, isophthalic acid (IA) 55.7 g, no hydroquinone (HQ) used, 4,4′-biphenol (BP) 249.6 g.

The solid state advancing was carried out for 30 minutes at 310° C. The DSC analysis gave temperature of crystallization of T_{c}=310° C. and the melt temperature of Tₘ=361° C. The melt viscosity at 370° C. and the shear rate of 100 seq⁻¹ was 1800 poise.

Table 2 summarizes the relative ratios of monomer units introduced into the acylation vessel for Examples 1 through 8.

TABLE 2
Composition of Polyester Resins, Molar Content of Structural Units

| | mol % | | | I, | | | |
|---|---|---|---|---|---|---|---|
| | V, | I/II, | IV/III, | mol % | mol % II, | mol % IV, | mol % III, |
| Example | pHBA | HQ/BP | I/T | HQ | BP | IPA | TPA |
| example 1 | 52.4% | 0.87 | 0.021 | 11.1% | 12.7% | 0.5% | 23.3% |
| example 2 | 65.0% | 0.99 | 0.055 | 8.7% | 8.8% | 0.9% | 16.6% |
| example 3 | 60.0% | 0.25 | 0.000 | 4.0% | 16.0% | 0.0% | 20.0% |
| example 4 | 60.0% | 0.25 | 0.040 | 4.0% | 16.0% | 0.8% | 19.2% |
| example 5 | 55.0% | 0.99 | 0.028 | 11.1% | 11.5% | 0.6% | 21.9% |
| example 6 | 60.0% | 0.60 | 0.042 | 7.5% | 12.5% | 0.8% | 19.2% |
| example 7 | 55.0% | 1.76 | 0.071 | 15.0% | 8.5% | 1.5% | 21.0% |
| example 8 | 60.0% | 0 | 0.333 | 0.0% | 20.0% | 5.0% | 15.0% |

The melting temperature (Tₘ) and the crystallization temperatures (T_{c}) for the resins formed in the examples are shown in Table 3.

TABLE 3
Melting Point and Crystallization Point of Polyester Resins

| Example | Tₘ, ° C. | T_{c}, ° C. |
|---|---|---|
| example 1 | 370 | 329 |
| example 2 | 382 | 338 |
| example 3 | 372 | 335 |
| example 4 | 368 | 330 |
| example 5 | 367 | 333 |
| example 6 | 367 | 337 |
| example 7 | 387 | 338 |
| example 8 | 361 | 310 |

Physical and color properties are summarized in Table 4.

TABLE 4
Physical Properties, Test Bars Molded from Neat Polyester Resins

| | | | ASTM, | Heat |
|---|---|---|---|---|
| | Resin | ASTM, Flex | flex stress | Deflection |
| | Powder, | strain at | at break, | Temperature, |
| Example | CIELAB ΔE* | break | psi | ° C. |
| example 1 | 20 | 3.7% | 21300 | 315 |
| example 2 | 19 | 2.0% | 15600 | 315 |
| example 3 | 22 | 3.3% | 18800 | 310 |
| example 4 | 21 | 3.8% | 21900 | 323 |
| example 5 | 20 | 3.7% | 18700 | 306 |
| example 6 | 20 | 4.7% | 20800 | 320 |
| example 7 | 18 | 2.0% | 8160 | 276 |
| example 8 | 24 | 3.8% | 19300 | 249 |

### Examples 9 Through 16

### Preparation of Glass-Filled Polyester Compounds Suitable for Use in the Manufacture of a Reflector of a Power LED Device

Samples of the polyester of the invention are compounded with reinforcing filler (fiberglass) and rutile TiO2 pigment. Compositions of compounded resins are shown in Table 5.

TABLE 5
Glass-filled Compounds

| | | Ex. | Ex. | Ex. | Ex. | Ex. | Ex. | Ex. |
|---|---|---|---|---|---|---|---|---|
| | Ex. 9 | 10 | 11 | 12 | 13 | 14 | 15 | 16 |
| | wt % | wt % | wt % | wt % | wt % | wt % | wt % | wt % |
| Polyester | 54 | 0 | 0 | 0 | 0 | 0 | 0 | 0 |
| of ex. 1 | | | | | | | | |
| Polyester | 0 | 54 | 0 | 0 | 0 | 0 | 0 | 0 |
| of ex. 2 | | | | | | | | |
| Polyester | 0 | 0 | 54 | 0 | 0 | 0 | 0 | 0 |
| of ex. 3 | | | | | | | | |
| Polyester | 0 | 0 | 0 | 54 | 0 | 0 | 0 | 0 |
| of ex. 4 | | | | | | | | |
| Polyester | 0 | 0 | 0 | 0 | 54 | 0 | 0 | 0 |
| of ex. 5 | | | | | | | | |
| Polyester | 0 | 0 | 0 | 0 | 0 | 54 | 0 | 0 |
| of ex. 6 | | | | | | | | |
| Polyester | 0 | 0 | 0 | 0 | 0 | 0 | 54 | 0 |
| of ex. 7 | | | | | | | | |
| Polyester | 0 | 0 | 0 | 0 | 0 | 0 | 0 | 54 |
| of ex. 8 | | | | | | | | |
| Rutile titanium | 24 | 24 | 24 | 24 | 24 | 24 | 24 | 24 |
| dioxide | | | | | | | | |
| Antioxidant/ | 1 | 1 | 1 | 1 | 1 | 1 | 1 | 1 |
| heat | | | | | | | | |
| stabilizer | | | | | | | | |
| fiberglass | 21 | 21 | 21 | 21 | 21 | 21 | 21 | 21 |

Compounding of neat polyesters synthesized according to examples 1 through 8 is accomplished as follows: the polyester resin, a rutile titanium dioxide commercially available from DuPont and a chopped fiberglass reinforcement commercially available from PPG are delivered via individual loss in weight feeders, in the weight ratios specified in above Table 5, to a Coperion ZSK-26 twin screw extruder comprising 12 barrels. The polyester and TiO₂ are delivered to barrel 1 whereupon the mixture is melted and dispersed before barrel 7. Anti-oxidants and heat stabilizers are similarly delivered at barrel 1. A side stuffer introduces fiberglass at barrel 7.

The fiberglass is distributed throughout the melted mixture in barrels 8 and 9 of the extruder. The new mixture is degassed via vacuum in barrel 10 of the extruder. That new mixture is compressed and cooled in barrels 11 and 12.

The thermal profile of the extruder is: no heat in barrel 1/360° C. in barrels 2 to 5/350° C. in barrels 6&7 /330° C. in barrel 8 /320° C. in barrel 9 /310° C. in barrels 10 and 11 and 300° C. in barrel 12. The screw rate is 350 rpm.

The extrudate from barrel 12 is cooled and pelletized with conventional equipment.

### Examples 17 Through 49

### Preparation of Unfilled Polyester Compounds Suitable for Use in the Manufacture of a Reflector of a Power LED Device

Samples of the polyester of the invention are compounded with rutile TiO₂ pigment, and optionally in addition with various optical brighteners, as detailed below:
BLANKOPHOR® BBH optical brightener, commercially available from BAYER, which is thought to include disodium 4,4′-bis{(4-anilino-6-morpholino-1,3,5-triazin-2-yl)amino}stilbene-2,2′-disulfonate;
CBS-127 optical brightener, commercially available from Jinan Subang Chemical Co. Ltd., which is thought to include 4,4′-bis[2-(2-methoxyphenyl)ethenyl]1,1′-biphenyl;
CBS-X optical brightener, commercially available from Jinan Subang Chemical Co. Ltd., which is thought to include 4.4′-bis(2-disulfonic acid styryl) 1,1′-biphenyl;
EASTOBRITE® OB-1 optical brightener, commercially available from EASTMAN Chemicals, which is thought to include 2,2′-(2,5-thiophenediyl)bis(5-(1,1-dimethylethyl)-benzoxazole;
EASTOBRITE® OB-3 optical brightener, commercially available from EASTMAN Chemicals, which is thought to include 2,2′-(1,2-ethenediyldi-4,1-phenylene)-bis-benzoxazole;
HOSTALUX® KCB optical brightener, commercially available from CLARIANT, which is thought to include 2,2′-(1,4-naphthalenediyl)bisbenzoxazole;
HOSTALUX® KSB optical brightener, commercially available from CLARIANT, which is thought to include one or more benzoxazole derivatives;
HOSTALUX® KSN optical brightener, commercially available from CLARIANT, which is thought to include one or more bisbenzoxazolylstilbene derivatives;
LEUKOPUR® EGM optical brightener, commercially available from SANDOZ, which is thought to include 7-(2H-naphtho[1,2-d]triazol-2-yl)-3-phenylcoumarin;
PHORWITE® K-20G2, commercially available from MOBAY Chemical Corporation, which is thought to include one or more pyrazoline derivatives.

Compositions of compounds are shown in Tables 6 to 8.

TABLE 6
Unfilled Compounds based on the polyester prepared in example 2

| | Ex. | Ex. | Ex. | Ex. | Ex. | Ex. | Ex. | Ex. | Ex. | Ex. | Ex. |
|---|---|---|---|---|---|---|---|---|---|---|---|
| | 17 | 18 | 19 | 20 | 21 | 22 | 23 | 24 | 25 | 26 | 27 |
| | wt % | wt % | wt % | wt % | wt % | wt % | wt % | wt % | wt % | wt % | wt % |
| Polyester of ex. 2 | 60 | 59.97 | 59.97 | 59.97 | 59.97 | 59.97 | 59.97 | 59.97 | 59.97 | 59.97 | 59.97 |
| Rutile titanium | 40 | 40 | 40 | 40 | 40 | 40 | 40 | 40 | 40 | 40 | 40 |
| dioxide | | | | | | | | | | | |
| BLANKOPHOR ® | 0 | 0.03 | 0 | 0 | 0 | 0 | 0 | 0 | 0 | 0 | 0 |
| BBH | | | | | | | | | | | |
| CBS-127 | 0 | 0 | 0.03 | 0 | 0 | 0 | 0 | 0 | 0 | 0 | 0 |
| CBS-X | 0 | 0 | 0 | 0.03 | 0 | 0 | 0 | 0 | 0 | 0 | 0 |
| EASTOBRITE ® | 0 | 0 | 0 | 0 | 0.03 | 0 | 0 | 0 | 0 | 0 | 0 |
| OB-1 | | | | | | | | | | | |
| EASTOBRITE ® | 0 | 0 | 0 | 0 | 0 | 0.03 | 0 | 0 | 0 | 0 | 0 |
| OB-3 | | | | | | | | | | | |
| HOSTALUX ® | 0 | 0 | 0 | 0 | 0 | 0 | 0.03 | 0 | 0 | 0 | 0 |
| KCB | | | | | | | | | | | |
| HOSTALUX ® | 0 | 0 | 0 | 0 | 0 | 0 | 0 | 0.03 | 0 | 0 | 0 |
| KSB | | | | | | | | | | | |
| HOSTALUX ® | 0 | 0 | 0 | 0 | 0 | 0 | 0 | 0 | 0.03 | 0 | 0 |
| KSN | | | | | | | | | | | |
| LEUKOPUR ® | 0 | 0 | 0 | 0 | 0 | 0 | 0 | 0 | 0 | 0.03 | 0 |
| EGM | | | | | | | | | | | |
| PHORWITE ® K- | 0 | 0 | 0 | 0 | 0 | 0 | 0 | 0 | 0 | 0 | 0.03 |
| 20G2 | | | | | | | | | | | |

TABLE 7
Unfilled Compounds based on the polyester prepared in example 4

| | Ex. | Ex. | Ex. | Ex. | Ex. | Ex. | Ex. | Ex. | Ex. | Ex. | Ex. |
|---|---|---|---|---|---|---|---|---|---|---|---|
| | 28 | 29 | 30 | 31 | 32 | 33 | 34 | 35 | 36 | 37 | 38 |
| | wt % | wt % | wt % | wt % | wt % | wt % | wt % | wt % | wt % | wt % | wt % |
| Polyester of ex. 4 | 60 | 59.97 | 59.97 | 59.97 | 59.97 | 59.97 | 59.97 | 59.97 | 59.97 | 59.97 | 59.97 |
| Rutile titanium | 40 | 40 | 40 | 40 | 40 | 40 | 40 | 40 | 40 | 40 | 40 |
| dioxide | | | | | | | | | | | |
| BLANKOPHOR ® | 0 | 0.03 | 0 | 0 | 0 | 0 | 0 | 0 | 0 | 0 | 0 |
| BBH | | | | | | | | | | | |
| CBS-127 | 0 | 0 | 0.03 | 0 | 0 | 0 | 0 | 0 | 0 | 0 | 0 |
| CBS-X | 0 | 0 | 0 | 0.03 | 0 | 0 | 0 | 0 | 0 | 0 | 0 |
| EASTOBRITE ® | 0 | 0 | 0 | 0 | 0.03 | 0 | 0 | 0 | 0 | 0 | 0 |
| OB-1 | | | | | | | | | | | |
| EASTOBRITE ® | 0 | 0 | 0 | 0 | 0 | 0.03 | 0 | 0 | 0 | 0 | 0 |
| OB-3 | | | | | | | | | | | |
| HOSTALUX ® | 0 | 0 | 0 | 0 | 0 | 0 | 0.03 | 0 | 0 | 0 | 0 |
| KCB | | | | | | | | | | | |
| HOSTALUX ® | 0 | 0 | 0 | 0 | 0 | 0 | 0 | 0.03 | 0 | 0 | 0 |
| KSB | | | | | | | | | | | |
| HOSTALUX ® | 0 | 0 | 0 | 0 | 0 | 0 | 0 | 0 | 0.03 | 0 | 0 |
| KSN | | | | | | | | | | | |
| LEUKOPUR ® | 0 | 0 | 0 | 0 | 0 | 0 | 0 | 0 | 0 | 0.03 | 0 |
| EGM | | | | | | | | | | | |
| PHORWITE ® K- | 0 | 0 | 0 | 0 | 0 | 0 | 0 | 0 | 0 | 0 | 0.03 |
| 20G2 | | | | | | | | | | | |

TABLE 8
Unfilled Compounds based on the polyester prepared in example 6

| | Ex. | Ex. | Ex. | Ex. | Ex. 4 | Ex. | Ex. | Ex. | Ex. | Ex. | Ex. |
|---|---|---|---|---|---|---|---|---|---|---|---|
| | 39 | 40 | 41 | 42 | 43 | 44 | 45 | 46 | 47 | 48 | 49 |
| | wt % | wt % | wt % | wt % | wt % | wt % | wt % | wt % | wt % | wt % | wt % |
| Polyester of ex. 6 | 60 | 59.97 | 59.97 | 59.97 | 59.97 | 59.97 | 59.97 | 59.97 | 59.97 | 59.97 | 59.97 |
| Rutile titanium | 40 | 40 | 40 | 40 | 40 | 40 | 40 | 40 | 40 | 40 | 40 |
| dioxide | | | | | | | | | | | |
| BLANKOPHOR ® | 0 | 0.03 | 0 | 0 | 0 | 0 | 0 | 0 | 0 | 0 | 0 |
| BBH | | | | | | | | | | | |
| CBS-127 | 0 | 0 | 0.03 | 0 | 0 | 0 | 0 | 0 | 0 | 0 | 0 |
| CBS-X | 0 | 0 | 0 | 0.03 | 0 | 0 | 0 | 0 | 0 | 0 | 0 |
| EASTOBRITE ® | 0 | 0 | 0 | 0 | 0.03 | 0 | 0 | 0 | 0 | 0 | 0 |
| OB-1 | | | | | | | | | | | |
| EASTOBRITE ® | 0 | 0 | 0 | 0 | 0 | 0.03 | 0 | 0 | 0 | 0 | 0 |
| OB-3 | | | | | | | | | | | |
| HOSTALUX ® | 0 | 0 | 0 | 0 | 0 | 0 | 0.03 | 0 | 0 | 0 | 0 |
| KCB | | | | | | | | | | | |
| HOSTALUX ® | 0 | 0 | 0 | 0 | 0 | 0 | 0 | 0.03 | 0 | 0 | 0 |
| KSB | | | | | | | | | | | |
| HOSTALUX ® | 0 | 0 | 0 | 0 | 0 | 0 | 0 | 0 | 0.03 | 0 | 0 |
| KSN | | | | | | | | | | | |
| LEUKOPUR ® | 0 | 0 | 0 | 0 | 0 | 0 | 0 | 0 | 0 | 0.03 | 0 |
| EGM | | | | | | | | | | | |
| PHORWITE ® K- | 0 | 0 | 0 | 0 | 0 | 0 | 0 | 0 | 0 | 0 | 0.03 |
| 20G2 | | | | | | | | | | | |

Compounding of neat polyesters synthesized according to examples 2, 4 and 6 is accomplished as follows: the polyester resin, a rutile titanium dioxide commercially available from DuPont, and optionally in addition an optical brightener, are delivered via individual loss in weight feeders, in the weight ratios specified in above Tables 6, 7 and 8, to a Coperion ZSK-40 co-rotating intermeshing twin screw 40 mm extruder with 12 barrel sections, giving an L/D ratio of 48. The polyester and, when present, the optical brightener, are delivered to barrel 1, while the rutile titanium dioxide is delivered at barrel 2. The mixture is degassed via vacuum in barrel 10 of the extruder. It is compressed and cooled in barrels 11 and 12.

The thermal profile of the extruder is: 150° C. in barrel 1/360° C. in barrels 2 to 5/350° C. in barrels 6/340° C. in barrel 7/330° C. in barrel 8/320° C. in barrel 9/310° C. in barrel 10/300° C. in barrels 11 and 12. The screw rate is 300 rpm.

The extrudate from barrel 12 is cooled and pelletized with conventional equipment.

### Examples 1b Through 49b

### Manufacture of Power LED Devices Having a Reflector Made of Neat Polyester, Glass-Filled Polyester Compound or Unfilled Polyester Compound

Power LED devices of examples 1b to 49b are manufactured in a process that includes molding a reflector onto a frame, wherein the reflector is molded from one of the 49 corresponding above exemplified polyester materials (having the same number), which are either neat polyesters, or glass-filled polyester compounds or unfilled polyester compounds; thus, the power LED device of example 1b includes thus a reflector molded from the polyester material of example 1, the power LED device of example 2b includes a reflector molded from the polyester material of example 2, . . . and the power LED device (PLED) of example 49b includes a reflector molded from the polyester material (PEM) of example 49. Thus the following 49 Power LED devices (PLED) are manufactured [the polyester material (PEM) of which the reflector consists is into brackets]: PLED 1b (PEM 1), PLED 2b (PEM 2), PLED 3b (PEM 3), PLED 4b (PEM 4), PLED 5b (PEM 5), PLED 6b (PEM 6), PLED 7b (PEM 7), PLED 8b (PEM 8), PLED 9b (PEM 9), PLED 10b (PEM 10), PLED 11b (PEM 11), PLED 12b (PEM 12), PLED 13b (PEM 13), PLED 14b (PEM 14), PLED 15b (PEM 15), PLED 16b (PEM 16), PLED 17b (PEM 17), PLED 18b (PEM 18), PLED 19b (PEM 19), PLED 20b (PEM 20), PLED 21b (PEM 21), PLED 22b (PEM 22), PLED 23b (PEM 23), PLED 24b (PEM 24), PLED 25b (PEM 25), PLED 26b (PEM 26), PLED 27b (PEM 27), PLED 28b (PEM 28), PLED 29b (PEM 29), PLED 30b (PEM 30), PLED 31b (PEM 31), PLED 32b (PEM 32), PLED 33b (PEM 33), PLED 34b (PEM 34), PLED 35b (PEM 35), PLED 36b (PEM 36), PLED 37b (PEM 37), PLED 38b (PEM 38), PLED 39b (PEM 39), PLED 40b (PEM 40), PLED 41b (PEM 41), PLED 42b (PEM 42), PLED 43b (PEM 43), PLED 44b (PEM 44), PLED 45b (PEM 45), PLED 46b (PEM 46), PLED 47b (PEM 47), PLED 48 (PEM 48) and PLED 49b (PEM 49).

The molding is carried out by conventional molding techniques such as injection molding or compression molding. During this molding the polyester material is subjected to high temperature, i.e. a temperature greater than the melting temperature of the polyester.

The resulting part that contains the reflector molded onto a lead frame is then bonded to a chip that provides the LED function to the device. The Power LED is bonded to the lead frame by soldering. The soldering process includes subjecting a least a portion of the lead frame and chip to temperatures of over 300° C. as the lead frame is contacted with a molten solder composition. The chip is wirebonded to the lead frame after the chip has been connected to the lead frame. Wire bonding includes soldering which again subjects the Power LED device to temperatures that are greater than 300° C.

The wire-bonded device is then encapsulated with a synthetic material such as a thermosetting or thermoplastic composition. Encapsulation typically involves curing the synthetic material at an elevated temperature (e.g., 60-180° C.) for a period from 0.5 to 6 hours to form the Power LED device.

The Power LED device is further subjected to another heat cycle as it is mounted onto a printed circuit board. The Power LED device is affixed to the printed circuit board by soldering during which portions of the Power LED device are contacted with a molten solder composition.

In addition to the above mentioned process steps a further drying step is carried out. The drying functions to remove water which may have been absorbed by any component of the Power LED device during its manufacture. Drying is carried out under infra-red reflow conditions which include heating to temperatures as high as 260° C. for a period of minutes.

The Power LED devices are subject to high heat and radiative stress during operation and during manufacture which involves several cycles of exposure to high heat. The Power LED devices in accordance with examples 1b to 49b suffer from less light distortion and retain substantially higher emission efficiency after exposure to the high temperature and high intensity radiation, than prior art Power LED devices comprising a reflector made from other polyester materials, e.g. from aliphatic polyester-based materials.

1. A power LED device, comprising:
a light emitting diode (LED) and a reflector;
wherein the reflector comprises (i) at least 50% by weight of at least one aromatic polyester having at least 80 mol % of aromatic monomer units and/or (ii) at least 30% by weight of at least one wholly aromatic polyester.

2. The power LED device according to claim 1, having a lumen depreciation value L₉₉ of at least 1,000 hours when driven at 150 mA.

3. The power LED device according to claim 1, being capable of emitting at least 50 lumens of light for 50,000 hours when driven at 150 mA.

4. The power LED device according to claim 1, further comprising a heat sink in direct contact with the reflector.

5. The power LED device according to claim 4, wherein the heat sink comprises at least 50% by weight, based on the total weight of the heat sink, of one or more of the aromatic polyester and the wholly aromatic polyester.

6. The power LED device according to claim 1, further comprising a heat sink integral with the base of the reflector.

7. The power LED device according to claim 1, further comprising a heat sink in thermal contact with the exterior surface of the reflector and made of at least one metal.

8. The power LED device according to claim 1, wherein the reflector has a base, an open top and walls that form a reflector cavity;
wherein the LED is positioned on the interior surface of the base of the reflector inside the reflector cavity, and is in direct contact with the base of the reflector;
wherein the Power LED device further comprises a cured transparent resin covering the LED and at least partially filling the cavity of the reflector; and
wherein the Power LED device further comprises an anode lead and a cathode lead connected to the LED.

9. The power LED device according to claim 1, wherein the aromatic polyester and the wholly aromatic polyester comprise polymerized structural units derived from p-hydroxybenzoic acid, terephthalic acid, hydroquinone, and 4,4′-biphenol; and optionally isophthalic acid.

10. The power LED device according to claim 9, wherein the structural units derived from p-hydroxybenzoic acid are present in an amount of 40-80 mole %, the structural units derived from terephthalic and isophthalic acid are present in an amount of 10-30 mole %, and the structural units derived from hydroquinone and 4,4′-biphenol are present in an amount of 10-30 mole %, wherein mole % is based on the total number of moles of polymerized monomer units derived from p-hydroxybenzoic acid, terephthalic acid, hydroquinone, and 4,4′-biphenol; and isophthalic acid.

11. The power LED device according to claim 9, wherein the molar ratio of the structural units derived from hydroquinone to the structural units derived from 4,4′-biphenol is from 0.1 to 1.5.

12. (canceled)

13. The power LED device according to claim 1, wherein the reflector comprises at least 50% by weight of the wholly aromatic polyester.

14. The power LED device according to claim 1, wherein the reflector consists of at least one of the aromatic polyester and the wholly aromatic polyester.

15. The power LED device according to claim 1, wherein the reflector comprises at least one of the aromatic polyester and the wholly aromatic polyester, and at least one optical brightener.

16. The power LED device according to claim 1, wherein the aromatic polyester and the wholly aromatic polyester comprise at least one structural unit selected from the group consisting of:
structural units (I) derived from hydroquinone, 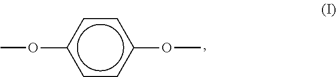
structural units (II) derived from 4,4′-biphenol, 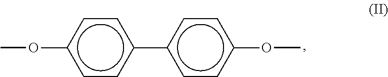
structural units (III) derived from terephthalic acid, 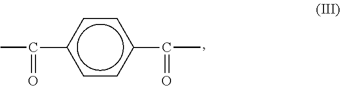
structural units (V) derived from p-hydroxybenzoic acid, 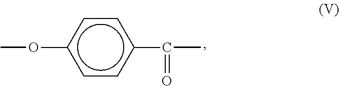
and
optionally in addition, structural units (IV) derived from isophthalic acid,

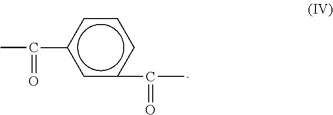

17. The power LED device according to claim 16, wherein the molar ratio of the structural units derived from isophthalic acid to the structural units derived from terephthalic acid is from 0 to 0.1.

18. The power LED device according to claim 9, wherein the molar ratio of the structural units derived from isophthalic acid to the structural units derived from terephthalic acid is from 0 to 0.1.
